(19) United States
(12) Patent Application Publication
(10) Pub. No.: US 2026/0362770 A1
(43) Pub. Date: Nov. 12, 2026

(54) LOW TEMPERATURE PROCESSED ULTRATHIN AMORPHOUS AND POLYCRYSTALLINE HOMOJUNCTION METAL OXIDE SEMICONDUCTORS

(71) Applicant: Trustees of Dartmouth College, Hanover, NH (US)

(72) Inventors: William J. Scheideler, Hanover, NH (US); Minh Nhut Le, Hanover, NH (US)

(21) Appl. No.: 19/672,301

(22) Filed: May 8, 2026

Related U.S. Application Data
(60) Provisional application No. 63/802,256, filed on May 8, 2025.

(51) Int. Cl. H10D 62/80; C23C 10/22; H10P 14/26

(52) U.S. Cl. CPC H10D 62/875; C23C 10/22; H10P 14/26

(57) ABSTRACT

A metal oxide film includes a homojunction structure with a metal oxide film. The homojunction structure has at least one crystalline layer that includes a metal and at least one less conductive layer that includes the metal. A roller can be used to apply the second workpiece onto a first workpiece such that the metal contacts the dielectric thereby forming an alloyed oxide film. The liquid printing may occur at a temperature of approximately 80 °C to 300 °C.

### CROSS-REFERENCE TO RELATED APPLICATIONS

This application claims priority to the provisional patent application filed May 8, 2025 and assigned U.S. App. No. 63/802,256, the disclosure of which is hereby incorporated by reference.

### STATEMENT REGARDING FEDERALLY-SPONSORED RESEARCH OR DEVELOPMENT

This invention was made with government support under 2202501, and 2219991 awarded by the National Science Foundation. The government has certain rights in the invention.

### BACKGROUND OF THE DISCLOSURE

In the era of the Internet of Things (IoT), the rapidly growing demand for flexible, wearable, and portable electronics has introduced challenges that conventional silicon-based materials struggle to meet, due to their inherent rigidity, brittleness, and limited mechanical flexibility. Recently, two-dimensional (2D) metal oxide materials from 1-5 nm thick have attracted attention as a promising alternative for high performance flexible electronics, offering exceptional mechanical flexibility combined with scalability and superior electronic mobility and conductivity as well as superlative interfaces to other 2D material systems such as transition metal dichalcogenides. These unique characteristics make 2D oxides particularly suitable for expanding the application of printed electronics into diverse domains such as personalized healthcare devices, wearable sensors, imaging, and information display.

Recently, atomic layer deposition (ALD) and sputtered oxides have demonstrated that ultrathin (1-6 nm) InOx and ITO can be utilized as semiconducting channels with a high density of states (DOS) that perform surprisingly well (Iₒₙ>2 mA/μm) in scaled (L_{g}<20 nm) channel-length devices, highlighting the state-of-the-art performance achievable. These advancements validate the intrinsic suitability of 2D oxides for next-generation electronics and motivate further exploration of alternative, scalable, and low-temperature fabrication methods for high-quality 2D oxide films. However, in many cases, 2D native oxides are highly substoichiometric and their relatively high oxygen vacancy concentrations result in high carrier concentrations that must be controlled for thin film transistor applications via composition or precise engineering of the channel layer thickness at the sub-nm scale.

Engineering ternary or quaternary 2D oxides via doping and alloying is known to control the high intrinsic carrier concentration of oxide semiconductors. Although aleovalent dopants such as Sn can produce degenerate ITO for transparent electrodes, they can also enhance semiconducting qualities of 2D InOx. Oxygen getters such as Ga are also well established to mitigate the oxygen vacancies and reduce the free carrier concentration (e.g. Ga-doping). It has been shown that doping with Sb, Sn, or Zn into the InOx system can improve both channel conductance and carrier mobility but generally comes with a tradeoff of increased off-current and weaker subthreshold slope. Amorphous oxide semiconductors combining Ga, Sn, and Zn (e.g. IGZO) are traditionally known to demonstrate steeper switching and improved bias-stress stability, but previous attempts to implement such quaternary 2D oxides using liquid metal printing have been confounded by mixed polycrystalline-amorphous phases and have utilized higher printing temperatures (300 °C).

2D oxides can advance closer to circuit level applications only if channel conductance can be controlled, uniformity can be enhanced, and bias-stress stability can be improved. Stabilizing the amorphous phase of 2D oxides while keeping high performance has not been achieved, though amorphous films are known to solve these issues based on decades of experience in the display industry. However, this also requires strategies to mitigate the well-established tradeoff between mobility and stability. The unique challenge in the case of 2D oxides for flexible electronics is the resulting need to engineer the properties of inorganic semiconductors at flex-compatible temperatures.

### SUMMARY OF THE DISCLOSURE

The present disclosure includes a solution to the abovementioned challenges for printed oxide electronics. In an embodiment, an amorphous phase of 2D InSnOx is grown over large areas using ultra-low temperature hypoeutectic liquid metal printing (80-300 °C). Further, embodiments disclosed herein include layered homojunctions of 2D oxides to integrate high-mobility front channels and high-stability back channels using variable Sn doping. Embodiments of the present disclosure can achieve superlative on-state performance while yielding steep turn on (e.g., steep switching below 100 mV/dec) and enhanced stability (e.g., 10× improvement in bias-stress compared with uniformly doped channels) simultaneously with high on-state performance.

The present disclosure includes a metal oxide film having a homojunction structure with a metal oxide film. In embodiments, the homojunction structure may include at least one crystalline layer including a metal and at least one less conductive layer that includes the metal.

In an aspect of the present disclosure, the less conductive layer may include a polycrystalline layer or an amorphous layer.

In an aspect of the present disclosure, the at least one crystalline layer and the at least one less conductive layer may form a multilayer channel with a front channel and a back channel.

In an aspect of the present disclosure, the front channel may include the at least one crystalline layer and the back channel may include the at least one less conductive layer.

In an aspect of the present disclosure, the at least one less conductive layer may include a ternary metal oxide.

In an aspect of the present disclosure, ternary metal cations of the ternary metal oxide may be vertically distributed in the metal oxide film via stacking of the layers.

In an aspect of the present disclosure, the metal may include In and the metal oxide film may be an InOx film.

In an aspect of the present disclosure, the metal may include In and the metal oxide film may be a metal-doped InOₓ film.

In an aspect of the present disclosure, the metal-doped InOₓ film may be indium tin oxide (ITO).

In an aspect of the present disclosure, the metal may include Sn and the metal oxide film may be an SnOₓ film.

In an aspect of the present disclosure, the metal may include Sn and the metal oxide film may be a metal-doped SnOₓ film.

In an aspect of the present disclosure, the distribution of the metal in the crystalline layer and the distribution of the metal in the less conductive layer may be uniform at the nanoscale.

In an aspect of the present disclosure, a single layer of the at least one crystalline layer and the at least one less conductive layer may be from 0.5-12 nm.

In an aspect of the present disclosure, the metal oxide film may be from 1-24 nm.

In an aspect of the present disclosure, the metal oxide film may have a 0.2-2% tensile strain.

In an aspect of the present disclosure, the metal oxide film may be a bilayer film.

In an aspect of the present disclosure, the metal oxide film may be a multilayer film.

In an aspect of the present disclosure, the metal oxide film may be nanocrystalline.

The present disclosure further provides a liquid printing method including providing a first workpiece having a surface that includes a dielectric, providing a second workpiece that includes a metal, and applying the second workpiece onto the first workpiece at a first pressure such that the metal contacts the dielectric thereby forming an alloyed oxide film. In an embodiment, the liquid printing may occur at a temperature of approximately 80 °C to 300 °C. Further, in embodiments, the first workpiece and/or the second workpiece may be heated from 100 °C to 300 °C.

In an aspect of the present disclosure, the first workpiece and the second workpiece may be substrates.

In an aspect of the present disclosure, the liquid printing may form a bilayer film.

In an aspect of the present disclosure, the liquid printing may form a multilayer film.

In an aspect of the present disclosure, the alloyed oxide film may be nanocrystalline.

In an aspect of the present disclosure, the metal may include In and the alloyed oxide film may be an InOₓ film.

In an aspect of the present disclosure, the metal may include In and the alloyed oxide film may be a metal-doped InOₓ film.

In an aspect of the present disclosure, the metal-doped InOₓ film may be indium tin oxide (ITO).

In an aspect of the present disclosure, the metal may include Sn.

In an aspect of the present disclosure, the alloyed oxide film may be one of InZnO, InGaZnOₓ, InGaSnOₓ, SnOx, InSnOₓ, GaSnOₓ, SbSnOₓ, InGaOₓ, InSbOₓ, or InZnSnOₓ.

In an aspect of the present disclosure, the dielectric may be SiOₓ, AlOₓ, YOₓ, HfOₓ, ZrOₓ, LaOₓ, another rare earth high-k dielectric, or an alloy thereof.

In an aspect of the present disclosure, the dielectric may be SiO₂, the metal may be In, the second workpiece may be applied using a roller. In embodiments, the applying may include rolling the roller over the first workpiece. A blade may be used with the roller to control a geometry of liquid metal meniscus.

In an aspect of the present disclosure, the first pressure using the roller may be from 0.1 N/cm of roller width to 100 N/cm of roller width.

In an aspect of the present disclosure, the applying further includes using a blade with the roller to control a geometry of liquid metal meniscus.

In an aspect of the present disclosure, the applying may form a homojunction structure.

### BRIEF DESCRIPTION OF THE FIGURES

For a fuller understanding of the nature and objects of the disclosure, reference should be made to the following detailed description taken in conjunction with the accompanying figures.

FIG. 1A displays an embodiment of a schematic of roller-based continuous liquid metal printing from In—Sn alloys showing variable amorphous versus crystalline phase versus Sn concentration.

FIG. 1B displays a thickness heatmap of an embodiment of a film of 2D ITO printed at 160 °C.

FIG. 1C displays an atomic force microscope (AFM) height image (top) and phase image (bottom) of crystalline 2D ITO (7 wt. % Sn) printed at 170 °C.

FIG. 1D displays an empirically determined phase diagram of ITO films as a function of printing temperature and Sn concentration.

FIG. 1E displays high-resolution transmission electron microscopy (HRTEM) image and selected-area electron diffraction (SAED) pattern of crystalline 10%-Sn 2D ITO after 250 °C annealing.

FIG. 1F displays a HRTEM image and inset is SAED pattern of amorphous 20%-Sn 2D ITO after 250 °C annealing.

FIG. 2A displays a Sn atomic percentage in the oxide as a function of Sn wt. % in the alloy.

FIG. 2B displays x-ray photoelectron spectroscopy (XPS) measurements of the Oxygen 1s peaks for 2D InSnOₓ films with varying Sn composition printed from alloys with 10-40 wt % Sn. The Ols peak is fit with three subpeaks corresponding to the binding energies associated with lattice oxygen, oxygen vacancy defects, and hydroxide species.

FIG. 2C shows x-ray photoelectron spectroscopy (XPS) measurements of the In 3d peaks for 2D InSnOₓ films with varying Sn composition printed from alloys with 10-40 wt % Sn.

FIG. 2D shows an x-ray photoelectronic spectroscopy depth profile revealing the varying composition vs. depth of a homojunction film composed of a tin-rich 2D InSnOx layer (printed from a 40 wt % alloy) and an underlying 2D InSnOx layer printed from a 10 wt. % Sn alloy.

FIG. 2E shows a Tauc plot of the optical absorption of multilayer 2D InSnOx films used to extract the optical bandgap of each film.

FIG. 2F shows a plot of the Urbach tails extracted from the optical absorption of the 2D InSnOx films used to extract a characteristic Urbach energy for each film.

FIG. 3A displays TFT bottom-gate structure using a homolayer as the channel.

FIG. 3B displays transfer characteristics of homolayer 2D ITO (20% Sn) films at different printing temperatures after post-annealing at 250 °C.

FIG. 3C displays transfer characteristics of homolayer 2D ITO films at 160 °C with different Sn % after post-annealing at 250 °C.

FIG. 3D displays a violin plot of mobility for 2D ITO films with different Sn concentrations after post-annealing at 200 °C and 250 °C.

FIG. 3E displays a TFT bottom-gate structure using a homojunction as the channel. As shown, an embodiment includes an O-deficient conductive front channel and an O-rich passivating back channel.

FIG. 3F displays transfer characteristics of homojunction 2D ITO films after post-annealing at 250 °C.

FIG. 3G displays incremental mobility versus gate voltage of homojunction 2D ITO after post-annealing at 250 °C.

FIG. 3H displays a violin plot of mobility for homojunction 2D ITO films printed at 150/160 °C.

FIG. 4A displays threshold voltage shifts for positive bias stress (PBS, V_{ds}=1 V, V_{gs}=30 V, 5500 s).

FIG. 4B displays threshold voltage shifts for negative bias stress (NBS, V_{ds}=1 V, V_{gs}=−30 V, 5500 s).

FIG. 4C displays extracted electronic density of state for homolayer 20%/20% and homojunction 20%/40% channel layers. The symbols shown are the extracted data for density of states and the dotted lines are biexponential fits to this data.

FIG. 5A displays a bottom-gate TFT structure and optical image of devices using solution-processed ZrO₂.

FIG. 5B displays transfer for homojunction 2D ITO (20%/40% Sn) films.

FIG. 5C displays output characteristics for homojunction 2D ITO (20%/40% Sn) films.

FIG. 5D displays a mobility histogram for homojunction 2D ITO (20%/40% Sn) films.

FIG. 5E displays a subthreshold swing histogram for homojunction 2D ITO (20%/40% Sn) films.

FIG. 5F displays a comparison of the linear mobility of printed transistors as described in Example 1, against other liquid metal printed 2D oxide transistors. The crystalline 2D oxide performance reported is shown.

FIG. 6 displays a grain size histogram of 2D ITO (7.5% Sn) printed 170 °C with 0.5 cm/s speed as extracted from the AFM scan shown in FIG. 1C.

FIG. 7A displays an XRD pattern of series of 2D ITO with variation of temperature and Sn % as-fabricated.

FIG. 7B displays an XRD pattern of series of 2D ITO with variation of temperature and Sn % after 250 °C post-annealed.

FIGS. 8A-8i displays a series of transfer characteristics of 2D ITO film post-anneal at 200 °C for 140 °C 3-prints 20% Sn (FIG. 8A), 150 °C 3-prints 20% Sn (FIG. 8B), 160 °C 3-prints 20% Sn (FIG. 8C), 150 °C 2-prints 20%/20% Sn (FIG. 8D), 150 °C 2-prints 20%/40% Sn (FIG. 8E), 150 °C 2-prints 10%/40% Sn (FIG. 8F), 160 °C 2-prints 20%/20% Sn (FIG. 8G), 160 °C 2-prints 20%/40% Sn (FIG. 8H), and 160 °C 2-prints 10%/40% Sn (FIG. 8I).

FIGS. 8J-8R display a series of transfer characteristic of 2D ITO film post-anneal at 250 °C and PMMA encapsulated for 140 °C 3-prints 20% Sn (FIG. 8J), 150 °C 3-prints 20% Sn (FIG. 8K), 160 °C 3-prints 20% Sn (FIG. 8L), 150 °C 2-prints 20%/20% Sn (FIG. 8M), 150 °C 2-prints 20%/40% Sn (FIG. 8N), 150 °C 2-prints 10%/40% Sn (FIG. 8O), 160 °C 2-prints 20%/20% Sn (FIG. 8P), 160 °C 2-prints 20%/40% Sn (FIG. 8Q), and 160 °C 2-prints 10%/40% Sn (FIG. 8R).

FIG. 9 displays transfer characteristic for temperature-dependent measurement of 2 layer homolayer 2D ITO 20%/20% and homojunction 2D ITO 20%/40% printed at 160 °C with speed of 0.5 cm/s after 250 °C post-annealed and PMMA encapsulation.

FIG. 10 displays a series of transfer characteristic of homojunction 2D ITO 20%/40% printed at 160 °C with speed of 0.5 cm/s after 250 °C post-annealed and PMMA encapsulation. V_{ds}=1V.

FIG. 11 displays meniscus contraction during traditional continuous liquid metal printing (CLMP) without confinement as the roller changes position.

FIG. 12 displays the liquid metal confinement (LMC) approach to print wide films in a single step.

FIG. 13A shows the contraction of the liquid metal meniscus into two separate droplets during unconfined CLMP printing thereby limiting the contact line, deposition area, and continuity of the film. FIG. 13B shows the confinement blade placed in front of the roller with a close up in the lower frame of the confined and uniform meniscus during printing. FIG. 13C shows LMC being achieved with two different blade distances from the roller and two different blade angles.

FIG. 14A shows a film deposited with a single roll step using LMC. FIG. 14B shows a film deposited by printing four adjacent strips with traditional CLMP. FIG. 14C shows a thickness heat map of the LMC film. FIG. 14D shows a thickness heat map of the traditional CLMP film. FIG. 14E shows a continuous film like that in 4a printed over >275 cm² in a single roll step.

FIG. 15 illustrates a method. Step a shows the substrate prior to the application of a Kapton mask. Step b shows the substrate covered with a patterned Kapton mask prior to plasma treatment. Step c shows selectively exposing the substrate to plasma treatment while shielding non-deposition areas with Kapton mask. Step d shows printing on a selectively plasma treated area where deposition only occurs on the regions of the substrate exposed to plasma. Step e shows the final patterned film deposited only where plasma treatment occurred.

FIG. 16 shows a continuous film deposited over a patterned film demonstrating the ability to fabricate films with different thicknesses in different regions.

FIG. 17 is a chart showing a trend in film thickness with print speed from 0.1 cm/s up to 20 cm/s.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Ranges of values are disclosed herein. The ranges set out a lower limit value and an upper limit value. Unless otherwise stated, the ranges include all values to the magnitude of the smallest value (either lower limit value or upper limit value) and ranges between the values of the stated range.

The steps of the method described in the various embodiments and examples disclosed herein are sufficient to carry out the methods of the present invention. Thus, in an embodiment, the method consists essentially of a combination of the steps of the methods disclosed herein. In another embodiment, the method consists of such steps.

Ultrathin 2D metal oxides are a high-performance class of transparent conducting materials capable of overcoming the traditional limitations of inorganic flexible electronics. The low temperature, thermodynamically favorable synthesis of 2D oxides at liquid metal interfaces offers the potential for printing these materials over large areas at unprecedented speeds with sub-nanometer scale precision in. However, these native oxides are substoichiometric and highly conductive, so new strategies are needed that can precisely engineer the electrostatics and enhance stability.

Embodiments of the present disclosure includes high-performance ultrathin oxide semiconductors that utilize multilayer channels to enhance electronic transport, control crystallinity, and improve device performance and stability. Embodiments of the present disclosure may enhance the performance of metal oxide thin film transistors for applications in flexible electronic circuits, information display technologies (LCD and LED displays, etc.), and back-end-of-line (BEOL) 3D integrated systems.

The present disclosure includes a low temperature method for controlling the fabrication of both amorphous and polycrystalline metal oxide semiconductors using vacuum-free processing and sub-nm control over film thickness at the wafer-scale.

Embodiments of the present disclosure include crystalline versus amorphous phase of 2D oxides via alloying of ternary In_{1-y}Sn_{y}Oₓ and utilize ultralow deposition temperatures (e.g., 130-160 °C) afforded by In—Sn eutectics. Embodiments of the present disclosure further include the rapid assembly of nanoscale (e.g., 0.5-12 nm per layer) vertical 2D homojunctions with electrostatically favorable grading from high density of states front channels to lower density of states back-channels. Materials characterization reveals the evolution of these amorphous 2D oxide channels and informs how this approach enhances electron mobility while simultaneously improving resilience under bias-stress, overcoming a common barrier to optimizing both performance and stability in metal oxide transistors. Embodiments of devices based on amorphous 2D oxide homojunctions achieve improved electron mobility (as high as 34 cm²/Vs), steep switching (as low as 100 mV/dec), and 10× reduced bias-stress shifts, presenting an improved strategy for high performance flexible oxide electronics.

An embodiment of the present disclosure includes a metal oxide film with a homojunction structure with a metal oxide film. The homojunction structure may include at least one crystalline layer including a metal and at least one less conductive layer including the metal. The less conductive layer may be a polycrystalline layer or an amorphous layer. In an embodiment, the metal (such as Sn) may be uniform at the nanoscale for both the crystalline layer and the less conductive layer. For example, the distribution of Sn metal in the material may be uniform at the nanoscale for the crystalline layer and the less conductive later of the film.

In an embodiment, the crystalline layer and the less conductive layer form a multilayer channel with a front channel and a back channel. The front channel may include the crystalline layer and the back channel may include the less conductive layer.

The less conductive layer may include a ternary metal oxide. Further, the ternary metal cations of the ternary metal oxide may be vertically distributed in the metal oxide film via stacking of the layers. In an embodiment, a single layer of the crystalline layer may be from 0.5-12 nm. Further, a single layer of the less conductive layer may also be from 0.5-12 nm. A thickness can be controlled by using the kinetic control disclosed herein. Thus, the print speed can be controlled to vary the printed film thickness. Thinner thicknesses may be used with high carrier concentration materials such as InOx and InSnOx. For these materials, devices like thin film transistors can be manufactured if the thickness can be controlled to below 3 nm. Thicknesses from 1.5 nm to 2.5 nm have been shown to yield improved device characteristics. Other alloys beyond InOx and ITO may have thicknesses from 3 nm to 12 nm, such as, for example, InZnOx.

In an embodiment, higher printing temperatures may lead to thicker films. In embodiments, the metal oxide film may be from 1-24 nm. Embodiments of thicker films may be suitable as high-performance semiconductors, for example, if the film was doped to lower the free carrier concentration. Embodiments of thinner layers, such as 1-4 nm layers may offer high performance and better suitability for short channel devices.

Embodiments of the 2D metal oxide film may sustain tensile bending strain from 0.2% to 2% without fracture.

In embodiments, the metal may include In and the metal oxide film may be an InOₓ film. In other embodiments, the metal oxide film may be a metal-doped InOₓ film. For example, the metal-doped InOₓ film may be indium tin oxide (ITO). In other embodiments, the metal may include Sn and the metal oxide film may be an SnOₓ film. Even further, the metal oxide film may be a metal-doped SnOₓ film.

Embodiments of the present disclosure may include a liquid printing method. In an embodiment, the liquid printing method may include a first workpiece and a second workpiece. A surface of the first workpiece may include a dielectric and the second workpiece may include a metal. In an embodiment, the second workpiece may be applied onto the first workpiece at a first pressure such that the metal contacts the dielectric thereby forming an alloyed oxide film. In an embodiment, the liquid printing may occur at a low temperature, for example a temperature of approximately 80 °C to 300 °C. Further, in an embodiment, the first workpiece and/or the second workpiece may be heated to from 100 °C to 300 °C (specifically, from (180 °C to 175 °C). In an embodiment, the first workpiece and the second workpiece may be substrates.

In embodiments, printing at higher temperatures (such as at 300 °C) may create films with different stoichiometries (more oxygen rich rather than oxygen deficient). In an instance, the films may be flexible. In embodiments using ternary liquid metal alloys, printing may occur at temperatures below 100 °C. Lower printing temperatures provide potential compatibility with a broader range of polymers and substrate materials because the print temperature generally has to be lower to reduce the substrate deformation and shrinkage. Lower temperatures for printing also may be helpful to improve the compatibility with other process steps used in microelectronics. Compatibility with dielectrics and metals and other materials may require keeping temperatures low. This may be beneficial during manufacturing of material layers when relative coefficients of thermal expansion vary and there are residual stresses impacting the mechanical stability of the films. Lower temperatures also may be helpful for manufacturability, safety, and energy efficiency, which can be advantages compared with many vacuum based methods that have toxic precursors or fumes.

Lower print temperatures can increase flexibility by a factor of approximately 10×, from the range of 0.1-0.3% bending strain tolerance to 1-3% bending strain tolerance using materials disclosed herein. This is a 5-10× improvement over sputtered indium tin oxide and other vacuum deposited films that have residual stress and generally tolerate less bending strain. Amorphous phase of 2D oxides can aid the flexibility by reducing the Young's modulus and thereby limiting the bending stress that induces cracking.

In embodiments of the present disclosure, the orientation of the layers of the film may be controlled. The relative order of the thermal treatment (e.g., printing at 150 °C then heating at 150 °C or 250 °C versus printing at 250 °C directly) can enable control over the orientation of the film. High temperature printed films deposited at 250 °C have mixed orientation with both 111 and 100 oriented InOx crystallites. The low temperature printed films can be crystallized into single orientation (e.g., substrate oriented) 111 or 100 films depending on the doping (Sn, Sb, etc.). For example, the orientation of the layers with respect to the substrate may be controlled. In an embodiment, textured films may be formed. Embodiments of the textured films may be oriented with respect to the substrate which may help achieve better electrical performance due to the reduction in grain boundary scatting effects.

Embodiments of the method may include a post-annealing, or heating step. The post-annealing may allow for the control of the oxidation of the film and/or the crystallinity and texture of the film. In embodiments, the post-annealing may be performed at a low temperature to form films that are dominated by a single polycrystalline grain orientation. For example, (100) oriented or (111) oriented films can be formed. In embodiments that use low temperature annealing (e.g., from 80 °C to 175 °C), the films may have a stronger texture and may have a single orientation. In an embodiment, during the post-annealing, or heating step, the crystalline layer becomes fully crystallized, and the amorphous layer remains amorphous.

Embodiments of the present disclosure further include annealing the oxide semiconductor films in conditions such as in a heater water bath at from 70 °C to 100 °C or by annealing it at or near room temperature using UV-generated ozone gas to promote oxidation. Embodiments of the annealing steps are useful for both the polycrystalline and amorphous oxides and may apply to both single layer films, multilayer films, and the homojunction architectures disclosed herein.

Embodiments of the present disclosure may be compatible for any metal alloys, including alloys matching the compositions of the other 2D oxide layers, such as In—Sn alloys, In—Sb alloys, In—Zn allows, etc.

Embodiments of the present disclosure the dielectric may be a rare earth dielectric. For example, in embodiments SiOₓ, AlOₓ, YOₓ, HfOₓ, ZrOₓ, LaOₓ, another rare earth high-k dielectric, or an alloy thereof may be used. As discussed in the examples, there is an additional benefit of combining the high-k dielectric with the homojunction 2D oxide channel materials because the high-k dielectric may enhance the steepness of switching (a lower subthreshold slope) and reduce the hysteresis.

Embodiments of the present disclosure form high quality interfaces with low defect densities. The steep subthreshold swing that was observed indicates a low interface electronic trap density on the order of 10¹¹ cm⁻² or lower.

Embodiments of the liquid printing method disclosed herein may control the semiconducting properties of the homojunction channels described herein by modifying the speed of the liquid metal oxide growth and simultaneously transfer to the target substrate.

Embodiments of the present disclosure include a film with a graded composition, rather than an abrupt heterojunction interface between two different materials. Embodiments of the homojunction may include an interface between InSnOₓ layers having different ratios of In:Sn, for example, a 9:1 InSnOₓ layer coated with a 6:4 InSnOₓ layer. The advantage of these structures is that they can enable improved semiconductor performance as compared to a heterojunction. The homojunction compared with the heterojunctions have lower interfacial defect densities, steeper switching, and higher mobility.

Embodiments of the present disclosure have demonstrated the fabrication of ultrathin (2-IO nm) films of amorphous and polycrystalline ternary (e.g. In—Sn—O) metal oxide semiconductors. Embodiments may include vertical graded distributions of the ternary metal cations in these films via stacking of layers and kinetic control over the thickness (variable printing speed) using liquid metal printing. These results show that the distribution of electronically active defects can be controlled at the single nanometer scale in graded homojunctions with multiple layers of varying stoichiometry and metal cation composition. These homojunctions may include multiple layers with variable Sn and In content that engineer front channel and back channel layers with either amorphous or polycrystalline phases. These phases can be further controlled via thermal annealing or ultraviolet irradiation.

Results have shown that liquid metal printing allows for rapid integration at short time scales (printing in 1 second) of 2-6 nm single layers. Via metrology by reflectometry and spectroscopic ellipsometry testing has shown that high uniformity at the wafer scale can be achieved and areas of greater 100 cm² may be covered.

Embodiments of the present disclosure include liquid metal printing at low temperatures, specifically at a range that is more compatible with plastics.

Embodiments of the present disclosure include films that are flexible. For example, embodiments of the films have demonstrated good mechanical flexibility even at 1.5% tensile strain for 2D oxide films printed on polyimide substrates, which is a factor 3× larger than the bending strain tolerance of thicker sputtered films that have large residual stresses. Results show that films may be printed on plastic and that these films have good adhesion and good electrical properties comparable to those printed on glass. Additionally, embodiments of the films have good resistance to scratching compared with polymer materials processed at similar process temperature ranges. Embodiments of the present disclosure may include materials in the amorphous phase which may help to enhance the flexibility under cyclic bending stresses.

The present disclosure stern from the single nanometer-level control over electronic properties in stacked channel architectures, the tuning of the amorphous versus crystalline structure of ultrathin metal oxides, the ultrathin nature resulting in high mechanical flexibility, and the low residual stresses stemming from their low temperature deposition and ultrathin nature.

In an embodiment, materials may be deposited at low temperatures without vacuum equipment and may not require high temperature annealing steps. These features lead to lower residual stress and enhanced bending tolerance. Enhanced mechanical flexibility under mechanical strain (both tensile and compressive) has been demonstrated in embodiments because the layers are thin and are deposited at low temperatures, two factors which help to prevent fracture and reduce the residual stress to limit cracking and buckling. The advantages are in comparison with thicker channel materials made of traditional amorphous metal oxides such as 1GZO or IZO that have thicker channels with larger residual stresses that limit performance to low levels of bending strain (<0.5%) and fewer cycles of bending. Further, embodiments do not require lengthy high temperature annealing that induces stress, increases fabrication costs, and limit integration.

Embodiments of the 2D homojunction approach allows to control electronic properties without the need for vacuum equipment or extensive post annealing. This feature has advantages for process compatibility of multiple semiconducting oxide materials. For example, embodiments may integrate complementary n-type and p-type oxides that require oxidative or reducing annealing steps. Existing technologies for low temperature processed metal oxides have lower performance and usually require some form of activation annealing steps.

Embodiments of the present disclosure have high electron mobility and the homojunction provides the ability to manage the oxygen vacancies that are important for electrostatic control and for bias stress stability. One of the significant performance advantages is that embodiments achieve high electron mobility but maintain good operational stability. This capability stems from the independent control over oxygen deficient and oxygen rich layers in the channel architecture which are, respectively, which may be beneficial for high channel electron mobility and high stability under transverse electric fields (e.g. positive or negative bias stress during operation). Another capability that it enabled is greater electrostatic control for additional channel length scaling, which may be important for back-end integration that could utilize submicron channel length devices for enhancing integration density, lowering power consumption, and increasing operating frequency. Compared with amorphous TGZO channel architectures or IZO channel architectures, embodiments of the present disclosure have the advantage of enabling ultralow temperatures for deposition and activation (<150 °C).

The present disclosure includes methods for amorphous homojunction deposition that enables control at the sub-nm level which is challenging or impossible to achieve with competing scalable methods such as sputtering for ultrathin channels. This may be essential for high density of states channel materials, such as amorphous ITO, given the electrostatic demand for ultrathin architectures that can be fully depleted to achieve low off-state current. Embodiments may utilize dopants for further tuning of the free carrier concentration and stability of these amorphous devices.

Because of the ultrathin nature of these materials, embodiments may require a high level of thickness uniformity to achieve consistent device properties across multiple samples and from one device to another within a wafer/substrate. The solution to this sensitivity is to utilize the self-limiting nature of liquid metal surface oxidation, which can serve to control the printing process to result in more uniform deposition.

Embodiments may enhance the uniformity and lower the variance of device properties such as the threshold and turn on voltages.

Embodiments of the homojunction structure may use embodiments of the multilayer structure as described herein to reduce the sensitivity to the thickness of the single front channel layer.

Ultrathin semiconductors tend to be more sensitive to their interfaces, meaning that sufficient passivation is required to stabilize the properties of these materials under environmental stresses and operational bias stresses. Embodiments may use materials and printing methods to overcome this. For example, oxygen rich amorphous compositions (with higher Sn concentration) may result in improved bias stress stability by reducing the oxygen vacancy concentration at the back-channel interface

The present disclosure may be used in thin film display technology, particularly for lightweight or flexible display applications. The materials and channel architectures included in the present disclosure could enhance the performance of pixel driving circuits in LCD and LED displays. Such designs can satisfy an industry-wide need to develop higher mobility channel materials and control variability and bias stress operational stability using amorphous metal oxides. They also can enhance the mechanical flexibility beyond past generations of metal oxide thin film device technology.

Embodiments of the present disclosure may include a scalable, low capital expenditure method for printing high performance metal oxide semiconductors from liquid metals. Embodiments may eliminate the need for various vacuum processing methods in the fabrication of large area flexible electronics. The commercial potential may also lie in applications to flexible sensor technologies that integrate signal processing and basic circuit-level functions such as multiplexing for integrating sensor arrays with wireless devices.

Embodiments of the homojunction channel architecture disclosed herein may satisfy both technological needs of metal oxide semiconductors. The commercial potential for this technology is in back end of line and interposer integrated microelectronic circuits based on metal oxides. The 3D integration that could be facilitated with these materials could enable integration of memory and competing technologies with lower latency and reconfigurability at chip level.

The following examples are presented to illustrate the present disclosure. They are not intended to be limiting in any matter.

### Example 1

This example provides a description of embodiments of the present disclosure.

This example applies an embodiment of kinetically controlled roller-based continuous liquid metal printing (CLMP) to achieve the deposition of large-area amorphous InSnOx films from hypoeutectic In—Sn alloys at ultra-low temperatures (140-160 °C). In contrast to the other 2D oxide thin-film transistor (TFT) studies which rely on crystalline oxide materials known for high mobility yet limited mechanical resilience, embodiments of the present disclosure exploit amorphous-phase 2D oxide layers that have the potential to offer enhanced mechanical flexibility and improved uniformity for large scale circuit applications. The method utilized in this embodiment involves the Cabrera Mott oxidation of the surface of a liquid metal meniscus. Because of the liquid nature of the parent metal alloy, the absence of strong macroscopic forces between the liquid metal and the thin 2D oxide layer facilitates clean exfoliation and transfer onto another substrate at temperatures below the melting point of the metal alloy.

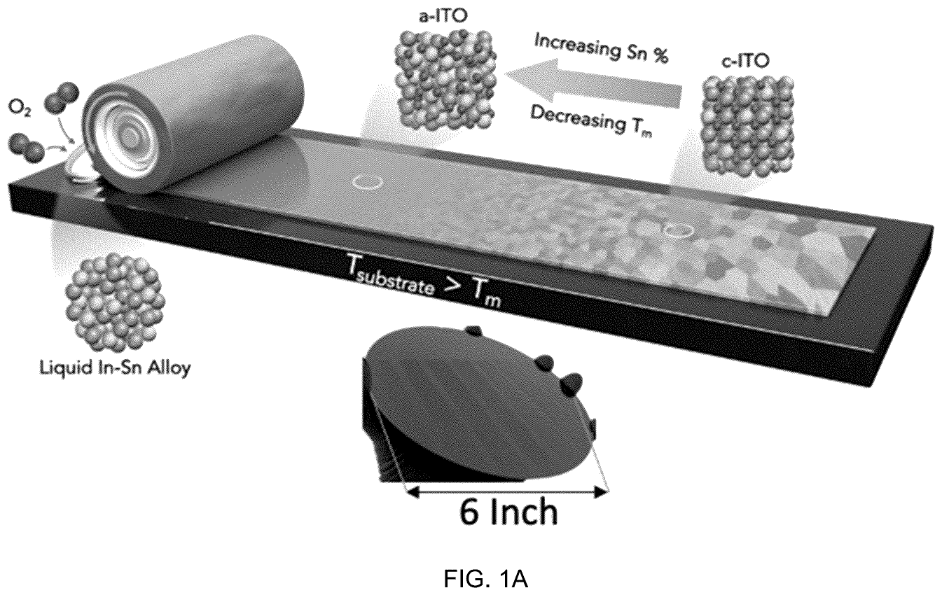

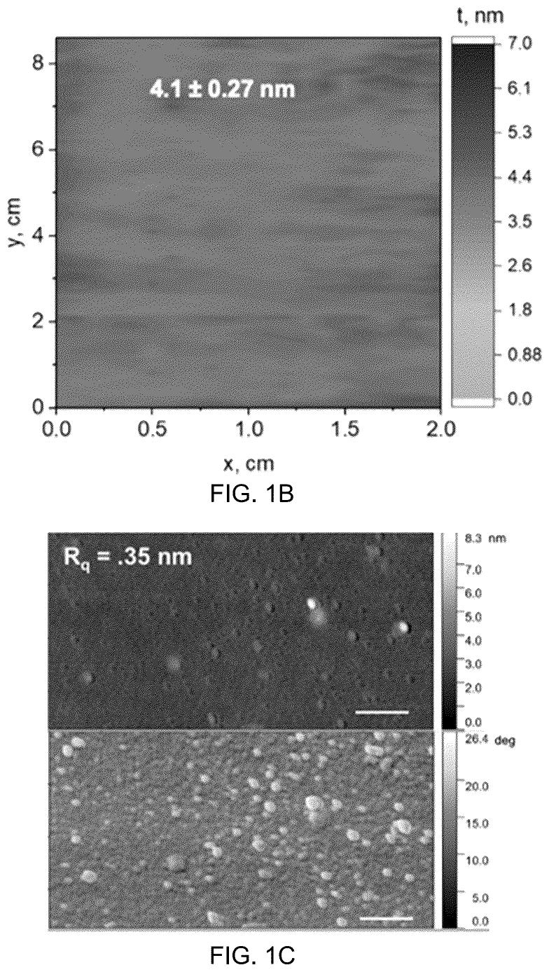

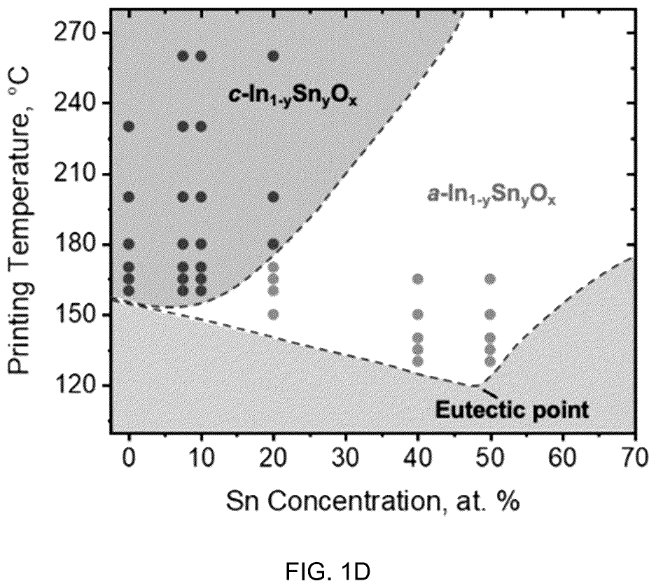

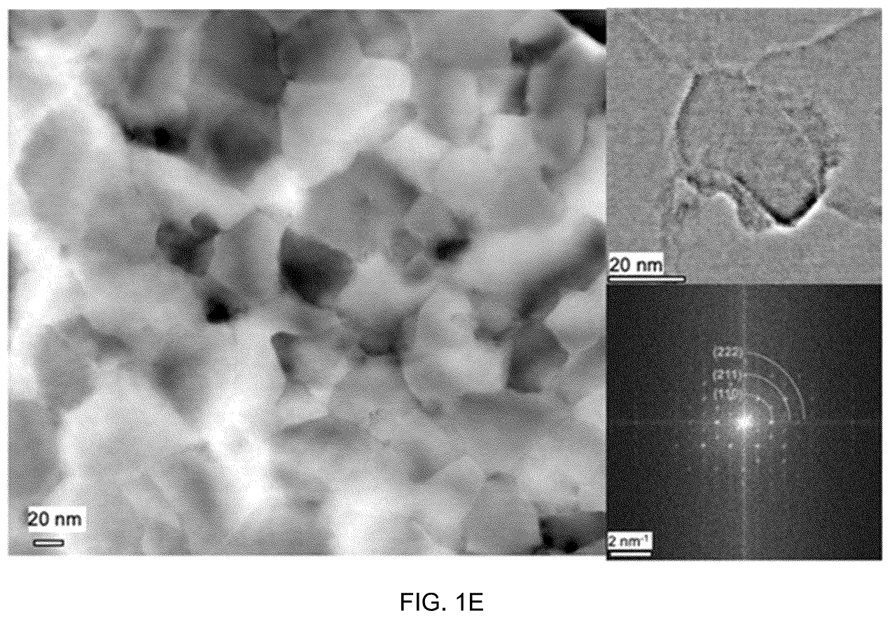

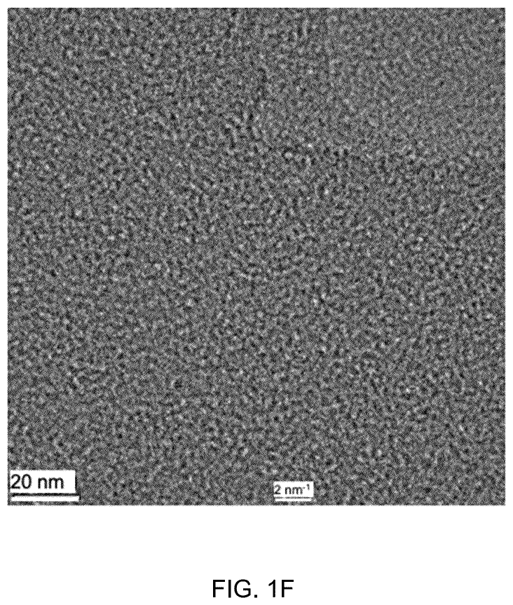

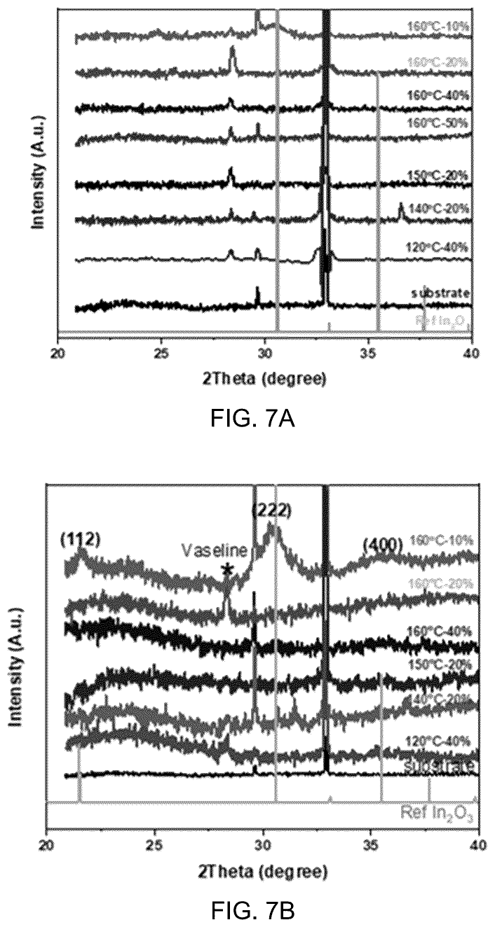

As illustrated in FIG. 1A, the deposition process involves heating the target substrate above the melting point of the alloy, followed by rolling the droplet across the substrate to translate the liquid metal meniscus and transfer the solid surface oxide continuously. The CLMP technique is scalable, performed under ambient conditions, and supports high-throughput, roll-to-roll compatible processing without the need for lengthy post-annealing due to the natively conductive phase of the substoichiometric 2D oxide. Furthermore, by leveraging variable Sn doping (up to 40%) and temperature the printed film can be controlled from crystalline (for 160 °C prints with 10% Sn as confirmed in FIGS. 7A-7B) to amorphous film (≤160 °C prints with 20% and 40% Sn, as confirmed in FIGS. 7A-7B). FIG. 1B shows a thickness heatmap of a single printed layer 2×8 cm ITO film as measured by spectroscopic reflectometry. The printed film by CLMP shows a uniform thickness from around 4.1±0.3 nm over the 16 cm² area. By variating the Sn concentration in In—Sn alloy and printing temperature, the crystalline versus amorphous nature of the film can be controlled which can be seen in FIG. 1D.

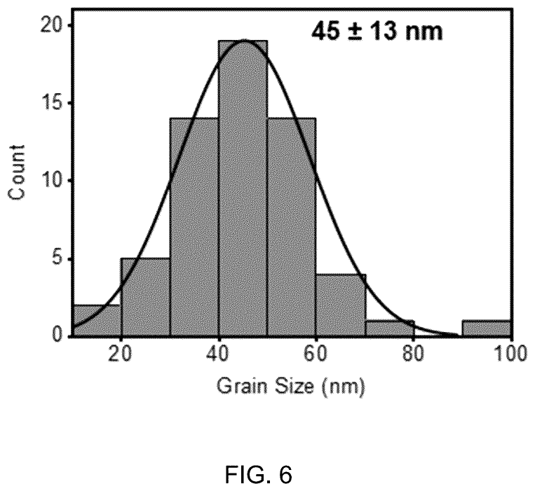

To systematically understand how the processing conditions lead to these different phases, a phase diagram based on experimental x-ray diffraction (XRD) analysis was constructed, as shown in FIG. 1D. Each data point in the diagram corresponds to a unique deposition condition and films characterized via XRD. The shaded regions denote empirically determined phase domains, revealing distinct windows in which either the amorphous or crystalline 2D oxide phases are deposited. This phase diagram shows two features. First, the heavier Sn doping closer to the eutectic point (approximately 1:1 wt %) enables lower temperature printing down as low as 130 °C, which is lower than existing liquid metal printing utilizing InOₓ. The second result of heavier Sn doping is that the amorphous phase can be maintained, even at higher temperatures that otherwise result in crystalline films. This enables control over the electronic properties and oxygen stoichiometry without inducing crystallization. Then the crystalline film morphology and grain size is studied by atomic force microscopy (AFM) height and phase image. AFM analysis (FIG. 1C) shows that the printed crystalline film has a smooth surface with a RMS (root mean square) roughness of 0.35 nm and an average lateral grain size of 45±13 nm (FIG. 6), showing the platelike, 2D shape of the grains in these films. High-resolution transmission electron microscopy (HRTEM) obtained by printing the films directly onto transmission electron microscopy (TEM (grids shows (FIG. 1E) the high crystallinity of the 2D ITO for lower Sn concentrations. The presence of distinct Moiré fringes further supports the formation of overlapping crystalline domains within individual prints, indicating substrate-aligned but non-epitaxial growth of the top and bottom surface oxide from the liquid metal meniscus. FIG. 1F shows a HRTEM image of the printed film prepared under the amorphous printing conditions, as defined within the amorphous regime of the phase diagram. The image reveals a uniform, featureless texture across the field of view, indicative of a smooth and amorphous film morphology. This is further supported by the selected area electron diffraction (SAED) pattern which displays diffuse concentric rings without sharp diffraction spots, which demonstrates the absence of long-range order.

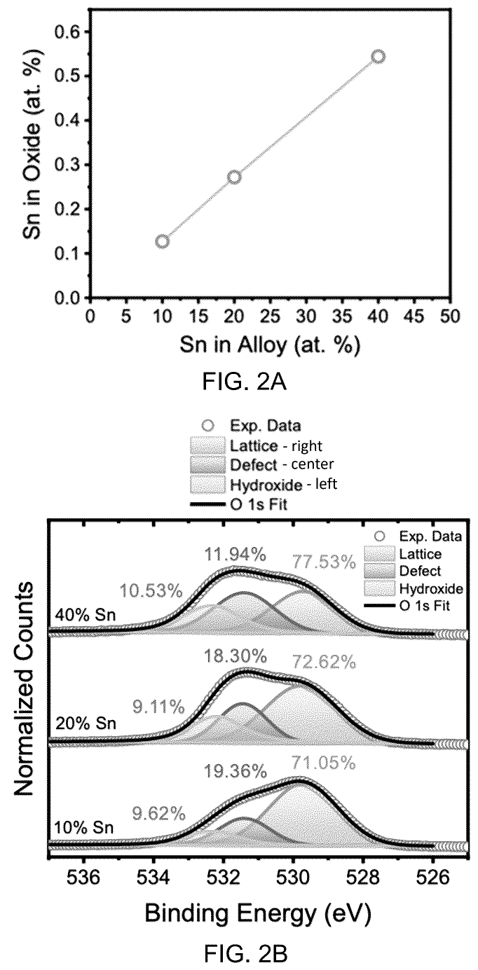

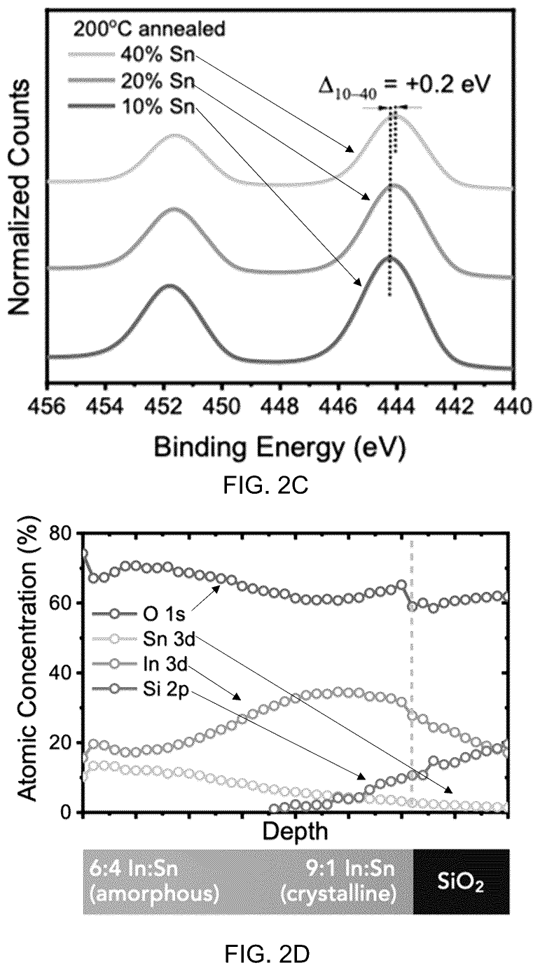

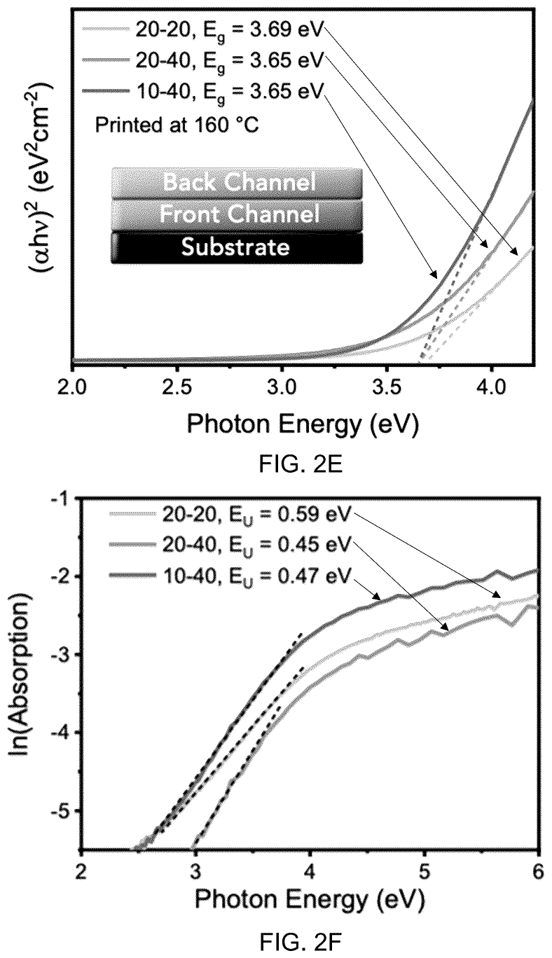

FIG. 2A of the x-ray photoelectron spectroscopy (XPS) analysis confirms that the Sn concentration in the 2D oxide film increases with the Sn content in the metal precursor alloy, with Sn slightly overrepresented (approximately 55% Sn in the oxide film vs. 40% wt. in the alloy). FIG. 2B show the XPS Ols spectrum of a film printed from alloys with 10, 20, and 40% Sn. These peaks can be deconvolved into three separate peaks centered at 529.7±0.1, 531.2±0.1, 532.2±0.1 eV metal-oxygen-metal bonds (M-O-M), metal-oxygen bonds near oxygen vacancies (M-O_{Vac}) and metal-oxygen bonds in hydroxylate or surface groups (M-OH), respectively. With increasing of Sn concentration, the portion of M-O-M bonding increases from 71.1% (10% Sn) to 77.5% (40% Sn) and the portion of M-O_{Vac} decreases from 19.4% (10% Sn) to 11.9% (40% Sn), indicating that with more Sn incorporation, the film retains more oxygen. This suggests that it should subsequently reduce the free carrier concentration and lower the Fermi level (E_{f}). FIG. 2C shows the In 3d spectrum of the ITO films with 10, 20 and 40% wt. Sn. The In 3d_{5/2} is centered at 444.3 eV and In 3d_{3/2} is centered at 451.8 eV for 10% showing that no metallic indium remained in the film and a 0.2 eV shift to lower energy level when doping more Sn also supports that greater Sn incorporation will reduce E_{f}.

The unique ability that rapid liquid metal printing affords is an opportunity to stack 2D oxides with varying electronic properties. In this example, 2D oxides with variable Sn doping into homojunctions with 3 nm to 5 nm thick layers were assembled. To fabricate the homojunction, first low Sn concentration layers were printed at the bottom and then higher Sn concentration layers were printed on top. The XPS depth profile study in FIG. 2D is conducted to confirm the formation of the homojunction of 10% on bottom and 40% on top (10%/40%). This result confirms that starting from the top layer to bottom layer, the In content gradually increases and Sn content decreases as expected. Unlike sol-gel processing or other high temperature methods, interdiffusion between layers is presumed to be limited due to the dense layers and low temperatures utilized here. Additionally, the oxygen portion of top layer is higher than the bottom, which supports the role of heavier Sn doping in oxygen vacancy suppression. Tauc plots in FIG. 2E based on optical absorption show the optical bandgap values of homolayer (20%/20%) and homojunctions (10%/40% or 20%/40%). The bandgap values of these film are similar, showing that the interface, unlike heterojunctions of InOx/GaOx, does not produce significant Burstein Moss shifts. FIG. 2F shows the Urbach energy comparison of the homojunctions and homolayers. Compared to 0.59 eV of 20%/20%, the 20%/40% and 10%/40% show lower Urbach tail energies of 0.45 eV and 0.47 eV, respectively. This indicates that the homojunctions have fewer optically active subgap defects than the homolayer.

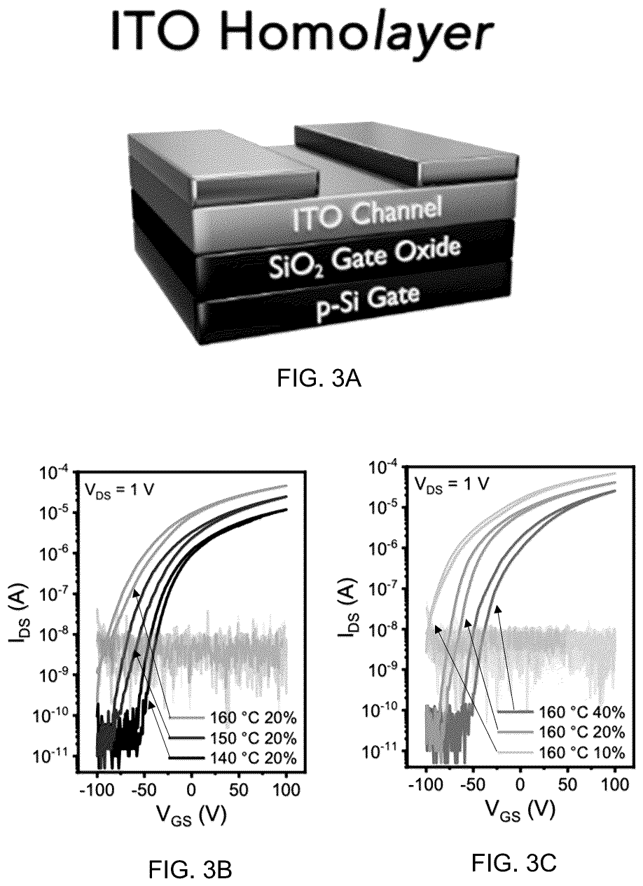

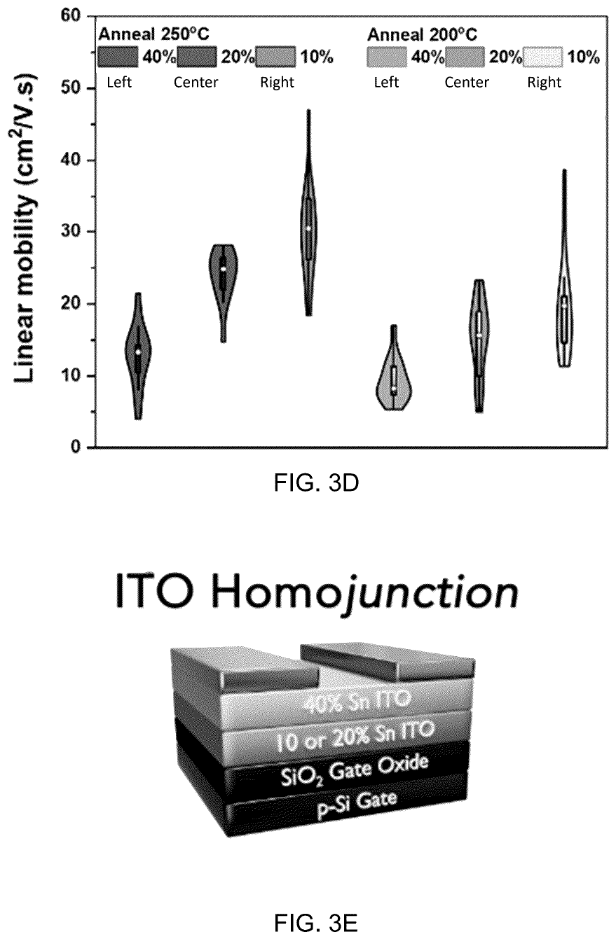

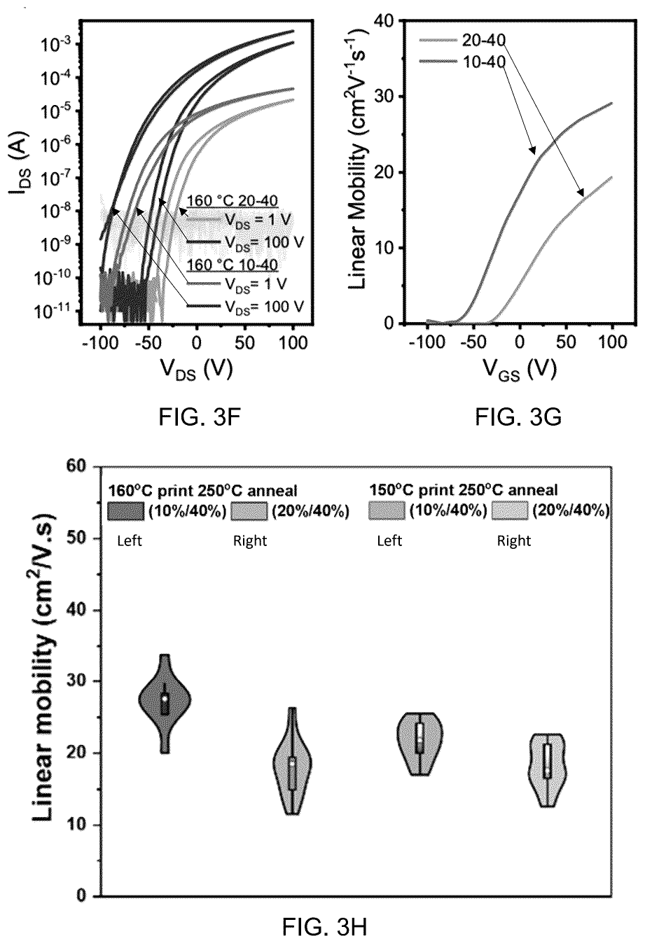

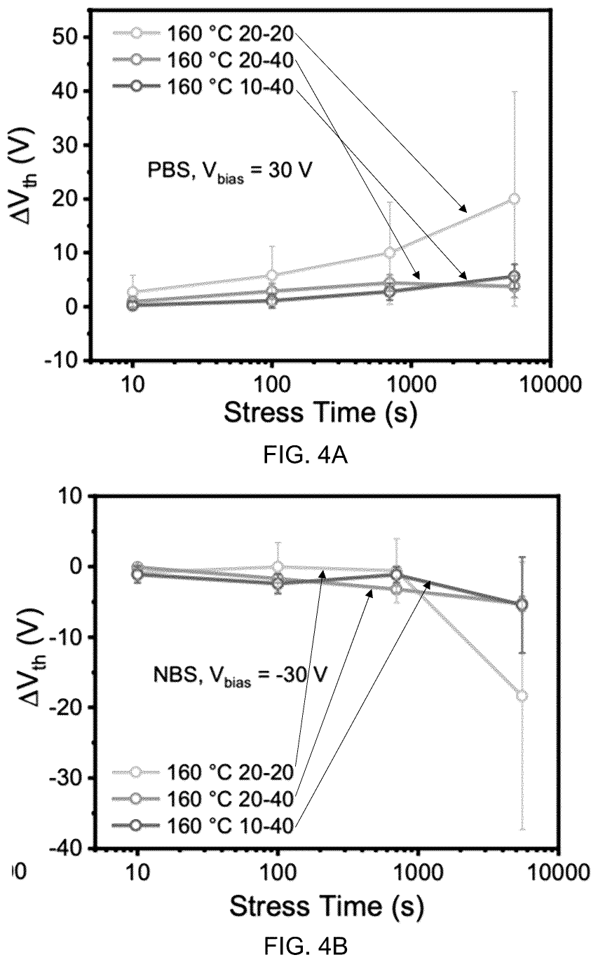

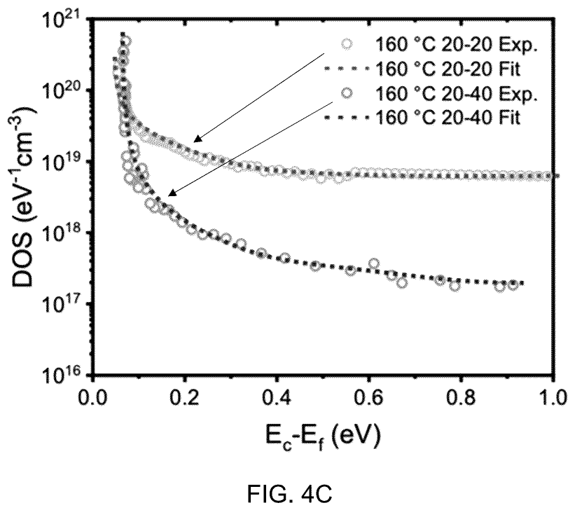

To study the effect of the vertical homojunction structures, the electrical performance of thin-film transistors (TFTs) fabricated with a homolayers (FIG. 3A) and homojunctions (FIG. 3E) were characterized. First, the effect of printing temperature on the electrical performance of 2D ITO films was investigated by fixing the Sn concentration at 20% and varying the printing temperature between 140 °C, 150 °C, and 160 °C. The transfer characteristics and a summary of the electrical performance are presented in FIG. 3A, Table 1, and Table 2. As the printing temperature increases from 140 °C to 160 °C, the mobility improves from 12.00 cm²/V s to 24.50 cm²/V·s. Meanwhile, the turn-on voltage (Von) and threshold voltage (Vₜₕ) shift negatively from −64.6 V and 16.6 V to −100 V and −10.8 V, respectively, indicating an increase in the free carrier concentration for the crystalline vs amorphous 2D ITO films with 10% Sn.

TABLE 1
Summary of 2D printed ITO TFT performance after 250 °C annealing. Champion values
are indicated with parentheses.

| | | | Number | | | | | |
|---|---|---|---|---|---|---|---|---|
| | | | of | Linear | | | | |
| | | Printing | Printed | Mobility | | | Subthreshold | Iₒₙ/ |
| N | Dielectric | Condition | Layers | (cm²/Vs) | Vₒₙ (V) | Vₜₕ(V) | Slope (V/dec) | I_{off} |
| 12 | 300 nm | 140 °C | 3 layers | 12.0 ± 3.3 | −64.6 ± 5.9 | 16.6 ± 6.7 | 1.5 ± 0.4 | 3.1 × |
| devices | SiO₂ | 20% | | (14.9) | | | (1.0) | 10⁶ |
| | | 150 °C | | 17.5 ± 2.2 | −93.3 ± 2.8 | 9.2 ± 2.6 | 1.4 ± 0.5 | 4.3 × |
| | | 20% | | (21.7) | | | (1.0) | 10⁶ |
| | | 160 °C | | 24.5 ± 3.1 | −100.0 | −10.8 ± 5.4 | 4.6 ± 4.1 | 1.0 × |
| | | 20% | | (30.1) | | | (0.9) | 10⁶ |
| | | 150 °C | 2 layers | 18.6 ± 3.8 | −70.3 ± 8.4 | 6.7 ± 9.9 | 1.5 ± 0.5 | 5.4 × |
| | | 20%-20% | | (22.7) | | | (1.0) | 10⁶ |
| | | 150 °C | | 18.3 ± 3.1 | −59.2 ± 6.1 | 17.6 ± 3.9 | 1.5 ± 0.4 | 4.7 × |
| | | 20%-40% | | (22.5) | | | (1.0) | 10⁶ |
| | | 150 °C | | 21.8 ± 2.7 | −79.1 ± 7.10 | 10.4 ± 8.4 | 1.4 ± 0.4 | 6.1 × |
| | | 10%-40% | | (25.5) | | | (1.0) | 10⁶ |
| | | 160 °C | | 30.0 ± 7.0 | −100.0 ± 0.0 | −26.9 ± 25.2 | 12.3 ± 21.9 | 1.6 × |
| | | 10%-10% | | (46.8) | | | (1.62) | 10⁵ |
| | | 160 °C | | 23.9 ± 3.8 | −83.7 ± 4.8 | −5.3 ± 14.1 | 1.9 ± 0.8 | 6.8 × |
| | | 20%-20% | | (28.0) | | | (1.1) | 10⁶ |
| | | 160 °C | | 12.8 ± 4.4 | −70.9 ± 15.3 | −5.7 ± 76.2 | 1.2 ± 0.5 | 4.8 × |
| | | 40%-40% | | (21.3) | | | (0.81) | 10⁶ |
| | | 160 °C | | 27.3 ± 3.3 | −85.9 ± 6.3 | −1.6 ± 3.1 | 1.3 ± 0.4 | 7.8 × |
| | | 10%-40% | | (33.7) | | | (0.80) | 10⁶ |
| 16 | | 160 °C | | 18.0 ± 3.8 | −45.4 ± 6.5 | 21.6 ± 5.5 | 1.3 ± 0.5 | 4.5 × |
| devices | | 20%-40% | | (26.3) | | | (0.85) | 10⁶ |
| 20 | Solution- | 160 °C | | 24.70 ± 3.30 | −4.9 ± 1.0 | 1.9 ± 1.9 | 0.4 ± 0.3 | 6.5 × |
| devices | processed | 20%-40% | | (29.9) | | | (0.10) | 10⁶ |
| | ZrOₓ | | | | | | | (2.68 × |
| | | | | | | | | 10⁷) |

TABLE 2
Summary of 2D printed ITO TFT performance after 200 °C anneal.

| Number | | | Number | | | | | |
|---|---|---|---|---|---|---|---|---|
| of | | | of | | | | | |
| devices | Dielectric | Sample | prints | Mobility | Von | Vth | SS | On/Off |
| 16 | SiO₂ | 140 °C | 3 prints | 8.80 ± 1.10 | −58.1 ± 11.0 | 28.2 ± 8.8 | 2.8 ± 0.6 | 2.2 × |
| devices | | 20%- | | (10.22) | | | (1.92) | 10⁶ |
| | | 3layer | | | | | | |
| | | 150 °C | | 10.80 ± 1.90 | −80.3 ± 9.2 | 17.8 ± 8.7 | 2.8 ± 0.6 | 2.3 × |
| | | 20%- | | (15.21) | | | (1.98) | 10⁰⁶ |
| | | 3layer | | | | | | |
| | | 160 °C | | 15.20 ± 5.20 | −68.3 ± 21.3 | 31.0 ± 12.8 | 1.9 ± 1.7 | 2.3 × |
| | | 20%- | | (23.16) | | | (0.90) | 10⁶ |
| | | 3layer | | | | | | |
| | | 150 °C | 2 prints | 5.40 ± 1.50 | −37.9 ± 13.7 | 63.2 ± 8.8 | 3.0 ± 1.0 | 4.5 × |
| | | 20%- | | (7.65) | | | (1.98) | 10⁶ |
| | | 20% | | | | | | |
| | | (ref | | | | | | |
| | | 2layer) | | | | | | |
| | | 150 °C | | 9.00 ± 2.30 | −42.9 ± 10.0 | 43.6 ± 8.2 | 2.6 ± 0.9 | 1.7 × |
| | | 20%- | | (11.64) | | | (1.60) | 10⁶ |
| | | 40% | | | | | | |
| | | 150 °C | | 11.20 ± 3.00 | −58.2 ± 14.1 | 39.0 ± 10.7 | 2.3 ± 0.5 | 1.8 × |
| | | 10%- | | (15.30) | | | (1.60) | 10⁶ |
| | | 40% | | | | | | |
| | | 160 °C | | 15.20 ± 5.20 | −65.5 ± 19.1 | 31.8 ± 12.9 | 4.1 ± 1.9 | 5.9 × |
| | | 20%- | | (23.16) | | | (1.53) | 10⁶ |
| | | 20% | | | | | | |
| | | (ref | | | | | | |
| | | 2layer) | | | | | | |
| | | 160 °C | | 13.40 ± 2.10 | −33.0 ± 14.5 | 44.3 ± 11.4 | 2.8 ± 0.9 | 3.3 × |
| | | 20%- | | (17.41) | | | (1.87) | 10⁶ |
| | | 40% | | | | | | |
| | | 160 °C | | 19.10 ± 3.70 | −39.6 ± 8.6 | 47.3 ± 5.7 | 3.1 ± 1.1 | 1.9 × |
| | | 10%- | | (24.49) | | | (2.01) | 10⁶ |
| | | 40% | | | | | | |
| | | 160 °C | | 12.30 ± 4.30 | −38.1 ± 9.6 | 44.6 ± 13.1 | 1.9 ± 3.2 | 2.3 × |
| | | 40%- | | (16.89) | | | (0.76) | 10⁶ |
| | | 40% | | | | | | |
| | | 160 °C | | 19.50 ± 7.30 | −70.2 ± 11.8 | 30.9 ± 10.7 | 3.5 ± 8.1 | 3.9 × |
| | | 10%- | | (38.50) | | | (0.70) | 10⁶ |
| | | 10% | | | | | | |

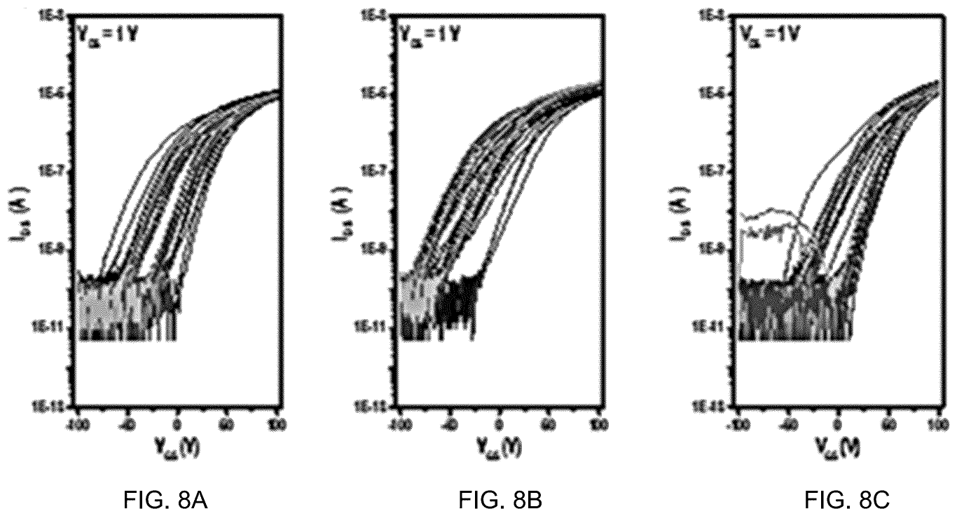

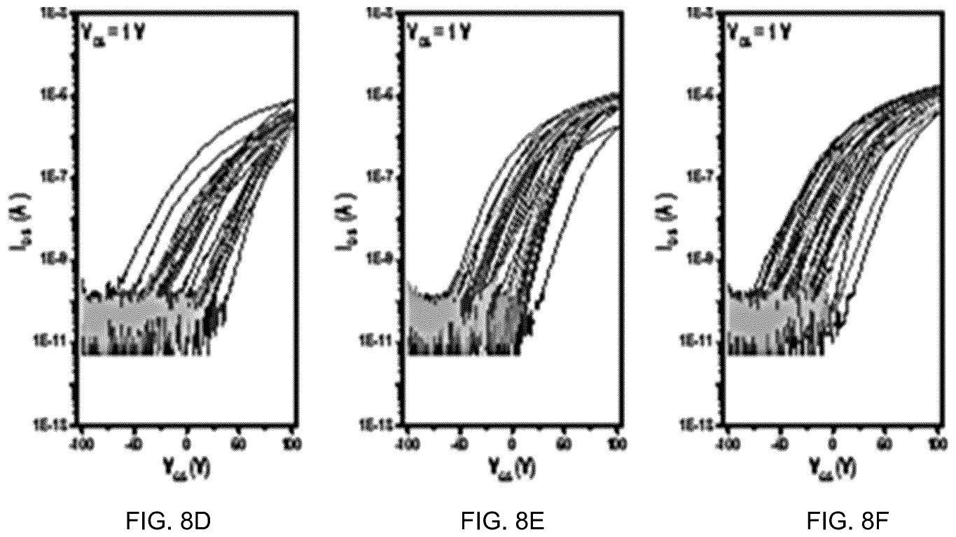

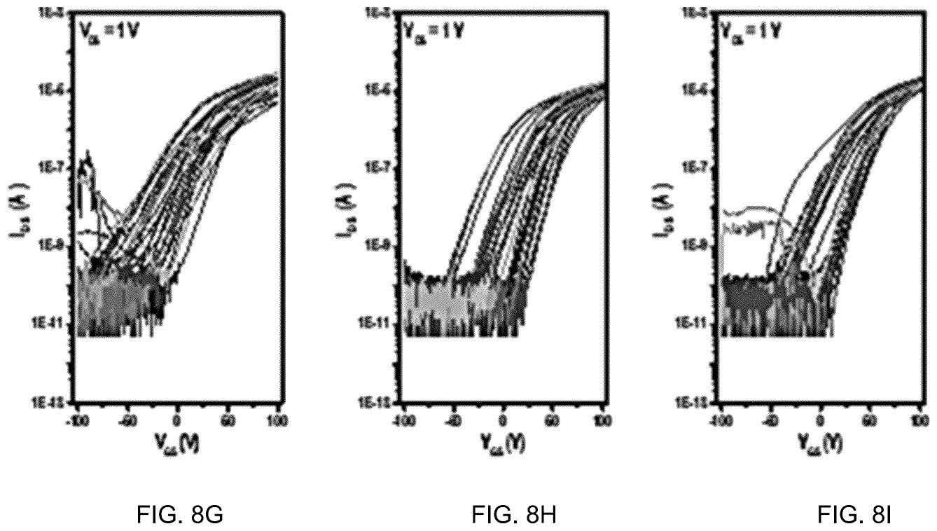

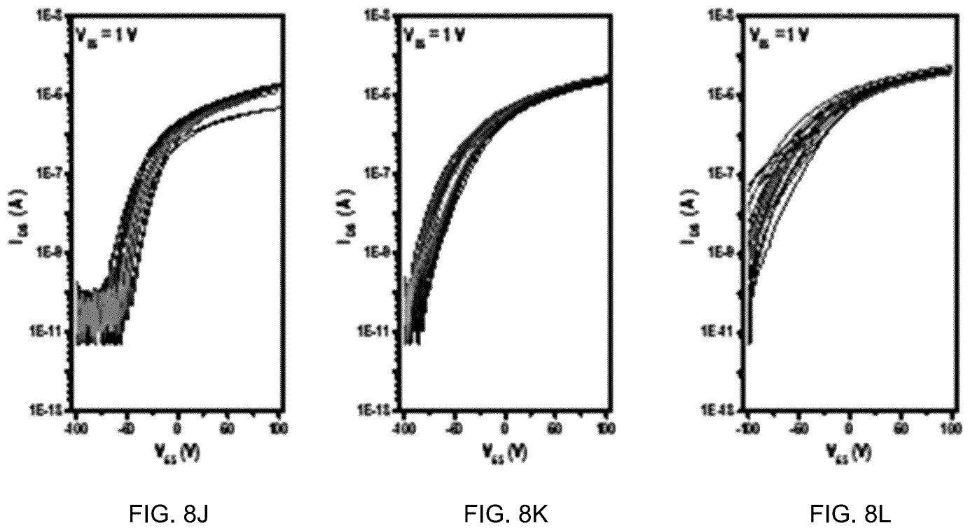

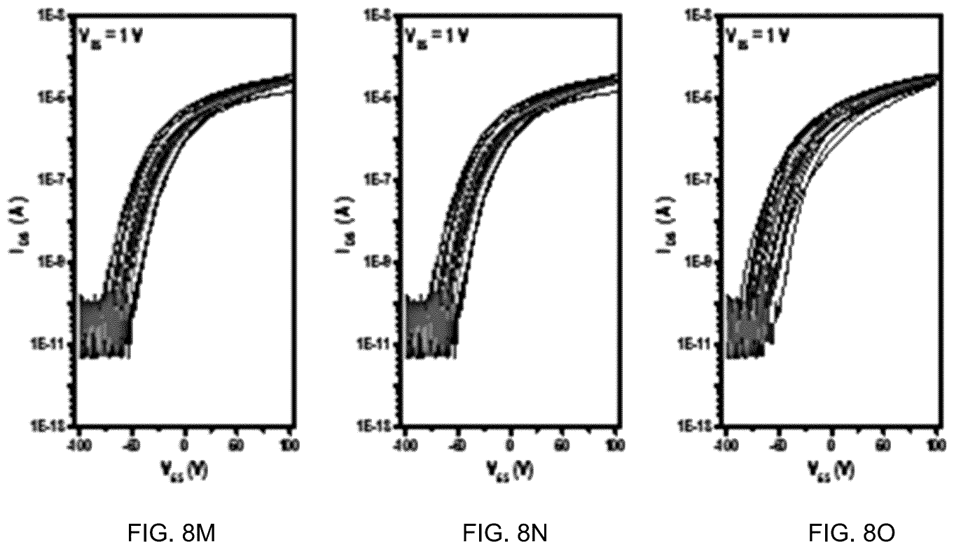

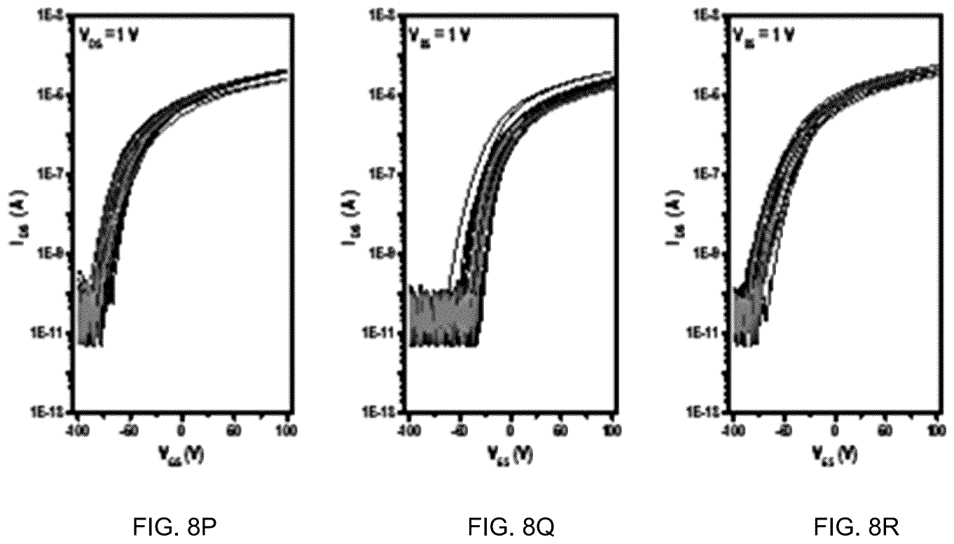

Next, the effect of different Sn concentrations on the performance of 2D ITO TFTs was examined. By maintaining printing temperature at 160 °C and varying Sn concentration from 10% and 20% to 40%, positive shifts in the turn on voltage with increasing Sn (FIG. 3C and Table 1) was observed. The 10% Sn-doped ITO film, with a crystalline nature confirmed by FIG. 7A-7B, exhibits a negative Vₒₙ and a high mobility of 30 cm²/V·s (with a maximum of 46.8 cm²/V·s). With increased Sn incorporation up to 40%, the mobility decreases to 12.8 cm²/V·s, while Vₒₙ and Vₜₕ shift closer to zero, indicating a lower carrier concentration. These trends are consistent with the XPS results discussed above. In addition, the violin plots shown in FIG. 3D and the series of transfer characteristics for different Sn % 2D ITO TFTs post-annealed at 200/250 °C (FIGS. 8A-8R) display a narrower distribution for high Sn % conditions (20%, 40%), supporting the improved uniformity of the amorphous channel devices compared to the crystalline channels of 10% Sn-doped condition.

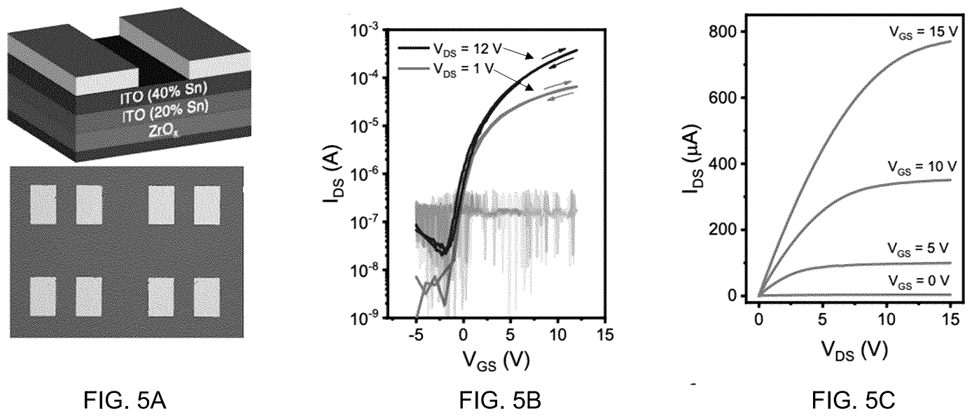

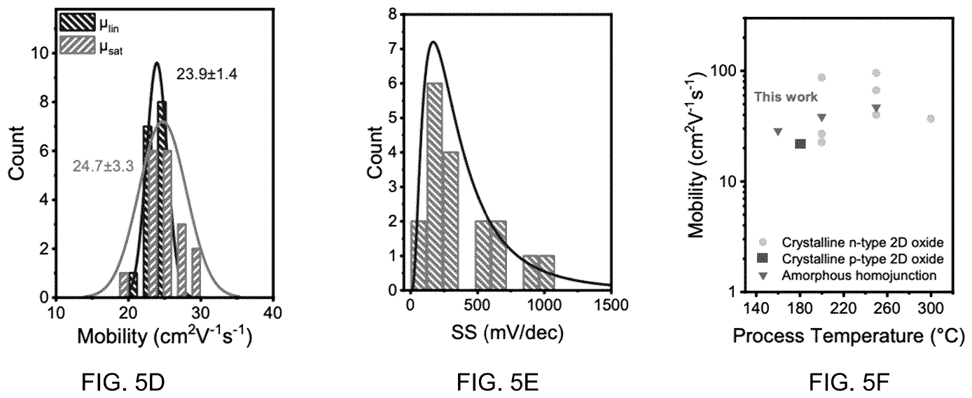

Two types of homojunctions, 10%/40% and 20%/40%, were investigated as shown in FIGS. 3F-3G, and Table 1. For the 10%/40% 2D ITO, due to the crystalline front channel with 10% Sn, the mobility reaches 27.3 cm²/V·s (maximum 33.7 cm²/V·s), slightly lower than the 10%/10% homolayer, while Vₒₙ and Vₜₕ shift more positively to −85.9 V and −1.6 V. In the case of the 20%/40% 2D ITO, the mobility is 18.00 cm²/V·s (maximum 26.3 cm²/V·s), with Vₒₙ and Vₜₕ shifting further positively to −45.4 V and 21.6 V. These shifts in both cases highlight the stabilization effect of the 40% Sn back channel. With the stabilization provided by the 40% Sn back channel, the violin plots for both types of homojunctions also exhibit tighter distributions. Furthermore, positive and negative bias stress tests comparing the homolayer and homojunction structures were conducted (FIGS. 5A-5B and Table 1). Under positive bias stress (PBS, V_{gs}=30 V, V_{ds}=1 V) and negative bias stress (NBS, V_{gs}=−30 V, V_{ds}=1 V) up to 5500 s, the ΔVₜₕ for the 20%/20% homolayer device degrades severely to 26.2 V (PBS) and −18.3 V (NBS). In contrast, the ΔVₜₕ shifts for the 20%/40% and 10%/40% homojunctions are lower: 2.8 V and −5.3 V for the 20%/40%, and 5.6 V and −5.4 V for the 10%/40%, respectively.

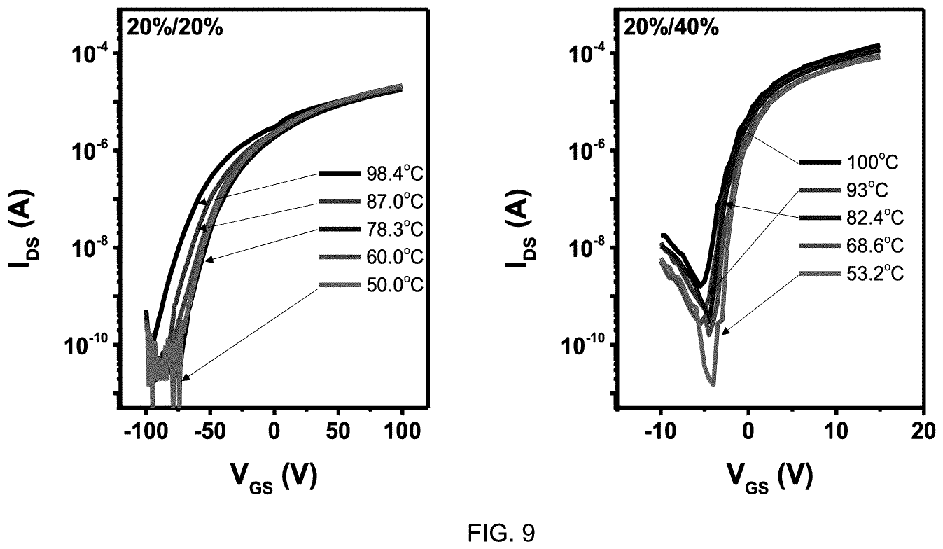

To further clarify the enhancement in bias stress stability, the sub-gap electronic density of states (DOS) was extracted for the homolayer (20%/20%) and homojunction (20%/40%) devices using temperature-dependent transfer measurements (FIGS. 9A-9B). The DOS extraction shown in FIG. 5C captures the combined contributions from the bulk channel and the front- and back-channel surfaces. The extracted density of states could be modeled approximately as a bi-exponential distribution of localized states, typical for disordered semiconductors, was observed for both devices. These distributions can be deconvolved into a linear superposition of exponential “tail states” near the band edges and exponential “deep states” further into the bandgap. The similar tail state densities explain the comparable mobility values for the 20%/20% and 20%/40% devices printed at 150 °C. (FIGS. 3D and 3H and Table 1). Additionally, the roughly 20× reduction in deep states for the homojunction device guarantees steeper switching and a lower subthreshold swing (SS), as evidenced by Table 1.

Finally, the 20%/40% homojunction was selected for integration with solution-processed high-k ZrO₂, achieving a balance of high mobility, Vₒₙ and Vₜₕ near zero, and outstanding bias stress stability (FIG. 5A). This result is an integration of liquid metal printed 2D oxide semiconductors with solution-processed high-k gate dielectrics. FIGS. 5B-5C show the champion transfer and output characteristics of the 20%/40% homojunction TFT, exhibiting a mobility of 29.9 cm²/V·s, Vₒₙ of −4.9 V, Vₜₕ of 1.9 V. The outstanding SS as low as 100 m V/dec and a remarkably small hysteresis both indicate the compatibility between liquid metal printed semiconductors and sol-gel high-k dielectrics such as ZrOₓ.

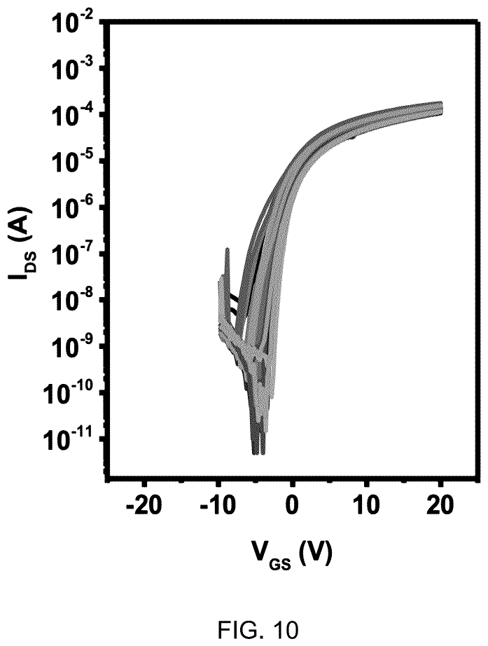

FIGS. 5D-5E and 10 further illustrate a tightly distributed histogram of linear and saturation mobility and SS values, as well as highly uniform transfer characteristics across 20 devices. It should be noted that studies relying on crystalline high-mobility phases often suffer from brittleness, poor bias stress stability, and low device uniformity. FIG. 5F presents the mobility achieved in the context of maximum processing temperature and structural state reported in the literature. While crystalline 2D oxides have demonstrated higher mobility (e.g., crystalline In₂O₃ achieving 96 cm²/V·s at 250 °C but with a low on/off ratio of 10⁴), embodiments of the present disclosure achieve a high mobility of 33.7 cm²/V·s for crystalline homojunctions and 29.9 cm²/V·s for amorphous homojunctions at 250 °C. At just 200 °C, mobilities of 24.5 cm²/V·s (crystalline) and 17.4 cm²/V·s (amorphous) were achieved, and at 160 °C, 28.64 cm²/V·s (crystalline) and 17.9 cm²/V·s (amorphous) were achieved.

Although the peak mobility values achieved in this example are lower than those reported for some crystalline 2D oxides, the superior bias stress stability, low hysteresis, and mechanical flexibility can offer advantages for long-term device operation. Within the context of amorphous 2D oxides, this example demonstrates a record-high mobility of 29.9 cm²/V·s for these 2D amorphous homojunctions, combined with bias stress stability and low hysteresis when integrated with a solution-processed ZrO₂ dielectric. These results highlight a promising pathway toward fully printed, flexible electronics based on ultrathin oxides. Furthermore, the amorphous nature of the film provides additional benefits for flexible applications, ensuring mechanical robustness under deformation.

Embodiments of the present disclosure present a strategy for controlling the amorphous versus crystalline phase of liquid metal printed 2D oxide semiconductors, revealing the potential for printing high performance oxide materials at ultralow temperatures near the eutectic point of indium-tin alloys (~118 °C). Sn-rich alloys control the free-carrier concentration and allow nanoscale vertical homojunctions with graded composition spanning crystalline and amorphous phases in the same film. Sn-rich amorphous homojunctions of InOSnOₓ optimize the balance between mobility and switching behavior while improving subthreshold swing and hysteresis, leveraging the high density of states (DOS) front-channel and a low DOS back-channel. Printed TFT devices incorporating solution-processed ZrO₂ dielectrics are demonstrated for amorphous 20%/40% 2D ITO homojunctions, producing a subthreshold slope and negligible hysteresis. These impressive device performances, combined with the facile, high-throughput, large-area, and cost-efficient continuous liquid metal printing method, demonstrate that this approach may be a promising strategy for scalable fabrication of next-generation flexible electronics.

Precursor Alloy Preparation: In this example, hypoeutectic In—Sn alloys were synthesized by melting indium (In, 99.995%, Luciteria) and tin (Sn, 99.99%, Luciteria) in a glass vial at 200 °C for 10 minutes under an inert nitrogen atmosphere inside a glovebox to minimize surface oxidation. Alloys with 10, 20, and 40 wt. % Sn were prepared by direct weighing then mixed by stirring with a glass tube when melt with above condition.

Continuous Liquid Metal Printing (CLMP): 2D metal oxide films were prepared by rolling a droplet of liquid metal alloy across 3×7 cm substrates using a silicone roller at a speed of approximately 5 cm/s on a hot plate set to 140, 150, or 160 °C. Before deposition, the substrates underwent surface activation using atmospheric plasma treatment for 30 seconds (Plasma Etch system, 1000 W, 30 LPM compressed dry air) to enhance film adhesion. For multilayer printing, each intermediate layer received a brief two-second plasma exposure to improve interlayer bonding. To ensure continuous and uniform film coverage, the target substrate was positioned between two sacrificial substrates of the same dimensions, which served as buffer zones at the start and end of the rolling path. The silicone roller was preconditioned by rolling it over a clean 300 nm SiO₂/Si substrate for one minute prior to printing. After deposition, residual liquid metal on the oxide film surface was cleaned using isopropyl alcohol (IPA), first while the sample remained heated, and again after cooling to room temperature.

TFT Device Fabrication: Thin-film transistors were fabricated using CLMP-printed metal oxide films on 300 nm SiO₂/Si substrates, following standard photolithography and wet etching techniques. The channel regions were patterned to dimensions of 150 μm in length and 200 μm in width. For 2D ITO channels, wet etching was performed using 18% HCl for 30 seconds. Source and drain electrodes were formed by sputtering approximately 30 nm of gold, followed by patterning via a lift-off process. Then the final devices were post-annealed at 200/250 °C (either 1, 2, or 24 hours) to enhance the performance.

For low-voltage operation, ~60 nm-thick ZrO₂ gate dielectrics were deposited onto heavily doped p-type silicon substrates. This was achieved by spin-coating a 0.2 M solution of ZrOCl₂ (reagent grade, 98%, Sigma-Aldrich) in 2-methoxyethanol at 3000 rpm for 40 seconds, followed by a soft bake at 150 °C for five minutes. This coating and baking cycle were repeated four times. The films were then post-annealed at 300 °C in ambient air for two hours.

To further enhance dielectric performance, the samples were soaked in hot deionized water at approximately 85 °C for 30 minutes. Then the next step for channel layer to finish the TFT device is same as described above.

Metal-insulator-metal (MIM) structures for gate capacitance measurements were prepared on the same substrate configuration using circular gold pads (area≈0.2 mm²) deposited via sputtering. Frequency-dependent capacitance was measured using a Hioki IM3570 LCR meter over the range of 100 Hz to 1 MHz.

Material Characterization: X-ray diffraction (XRD) analysis was conducted on three printed films deposited on silicon wafers coated with a 300 nm thermally grown SiO₂ layer. The measurements were carried out using a Rigaku Miniflex diffractometer equipped with Cu Kα radiation, operated at a scanning rate of 10° per minute. Transmission electron microscopy (TEM) was employed to characterize the 2D ITO films using a FEI Tecnai F20 microscope, operated at an accelerating voltage of 200 kV. For TEM observation, the 2D ITO films were directly printed onto carbon type-B 2000-mesh copper grids (Ted Pella) via the CLMP printing technique.

X-ray photoelectron spectroscopy (XPS) measurements were carried out using a Kratos Axis Supra instrument under ultra-high vacuum conditions (~10⁻⁹ Torr) on metal oxide films comprising four printed layers deposited on silicon substrates with a 300 nm SiO₂ layer. Optical absorbance spectra of the 2D ITO films were obtained using a Cary 60 UV-Vis spectrophotometer, scanning in the range from 200 nm to 800 nm with samples printed on borosilicate glass substrates. Film thicknesses were determined using Filmetrics F3 and F20-UV spectral reflectometers to measure oxide layers printed over 300 nm SiO₂/Si substrates. Surface morphology of the printed films was analyzed using an AIST-NT atomic force microscope (AFM). Optical images were captured using a Keyence VHX-7100 digital microscope.

Electrical Measurements: Thin-film transistor measurements, including both transfer and output characteristics, were performed in ambient conditions at room temperature using an Agilent E5260A semiconductor parameter analyzer. The electronic density of states (DOS) was determined from temperature-dependent transfer measurements taken in the linear regime under 1 V drain voltage, across a temperature range from room temperature up to approximately 100 °C. Extraction of the DOS was based on fitting an activation energy as a function of gate voltage, using the multiple trap-and-release (MTR) model as a theoretical framework. Bias stress stability was also evaluated using the same analyzer after encapsulating the devices with a layer of polymethyl methacrylate (PMMA 950A4).

### Example 2

This example provides a description of embodiments of the present disclosure.

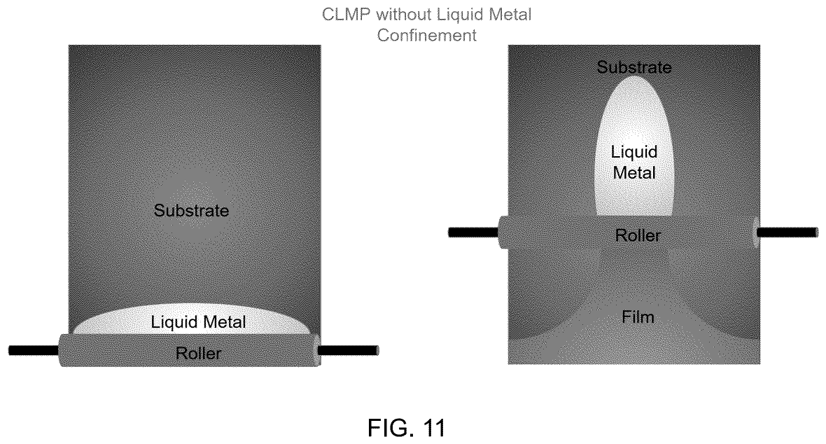

Continuous 2D metal oxide semiconducting and conducting films can be transferred from the surface of a liquid metal droplet to the surface of a dielectric substrate using a compliant roller. The metal whose oxide is to be printed on the substrate can placed on the substrate and melted by a hot plate. The roller can then be pressed down onto the substrate by pneumatic cylinders behind the, now melted, liquid metal droplet. After the blade and roller are in position, the hot plate and substrate are moved by the stage under the roller to deposit films in one deposition step. FIG. 1A show the metal oxide transfer process that is modified in this example. The embodiments of this example address the challenge of extending the contact line between the liquid metal meniscus and substrate along the length of the roller during printing in order to print large area, highly uniform, continuous films in a single deposition step. Traditional CLMP implementations have been limited to producing large area films by either printing long narrow strips or by printing multiple narrow adjoining strips in multiple deposition steps. This limitation stems from the interfacial tension of the liquid metals used in CLMP which causes even large droplets to contract in front of the roller during printing, which reduces the length of the contact line and, therefore, the width of the printed film. This is shown in FIG. 11.

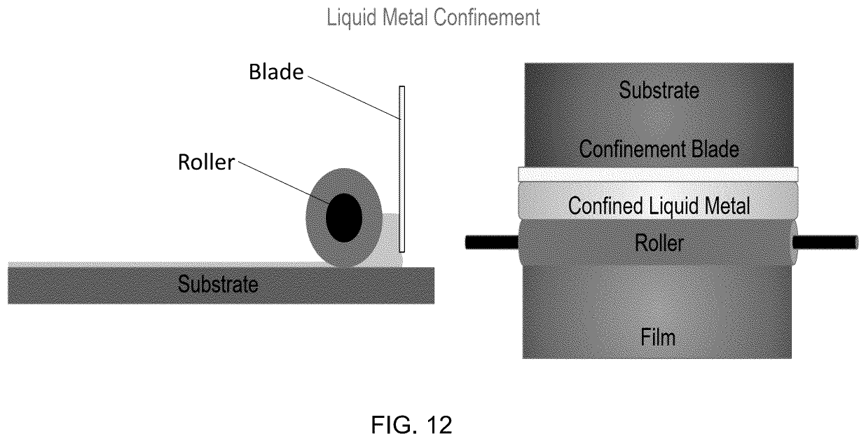

In an embodiment, the liquid metal meniscus may be confined during printing such that an extended contact line is maintained throughout the printing process allowing for single roll deposition of films of areas >100 cm². >250 cm² was demonstrated. A rigid blade is positioned in front of the roller such that the blade moves with the roller, effectively confining the liquid metal meniscus to a controlled volume and geometry. The blade is held a distance away from the roller (e.g., 0.1 mm to 10 mm) and is held between 0.1 mm and 5 mm above the substrate such that a gap is maintained between the blade and the substrate. The blade may not have a high level of rigidity, as it is not under a significant load. However, the surface material may be compatible with the precursor alloy to avoid corrosion or alloying between the blade and the precursor. The blade used in the example was made of brass and coated with Kapton tape. FIG. 12 shows an example of the system and operation.

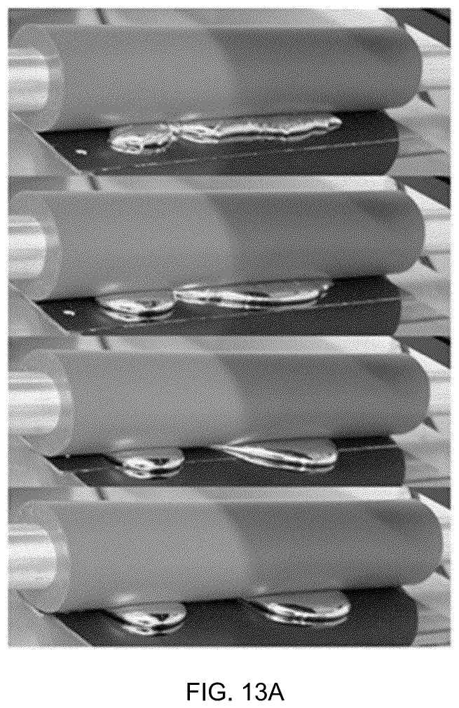

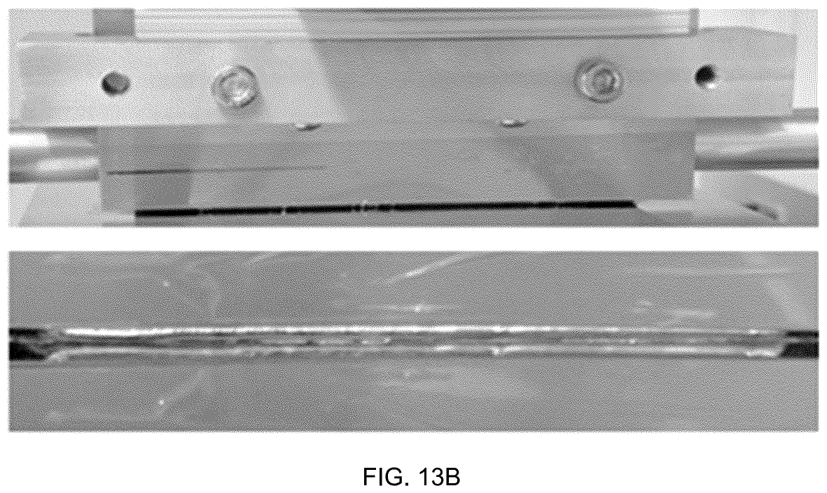

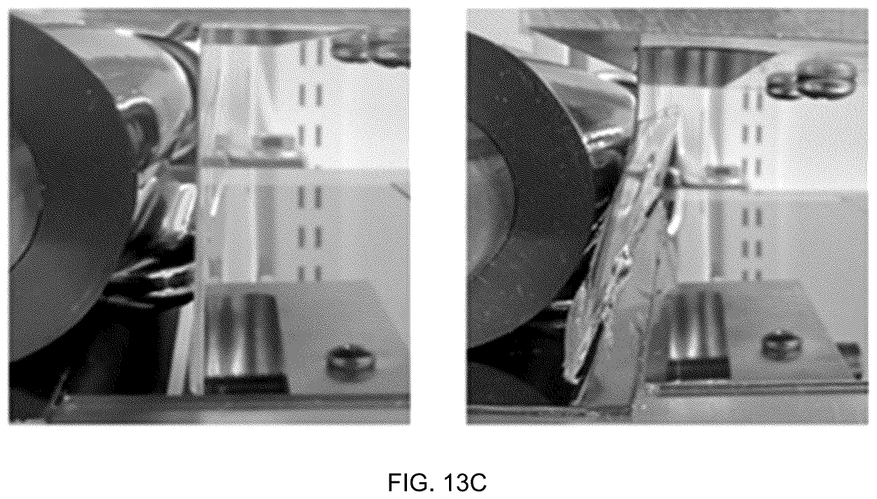

The geometry of liquid metal meniscus can be controlled during printing to tune properties and dimensions of deposited films by varying the distance between the blade and the roller, the distance of the blade from the surface of the substrate, and the angle of the blade with respect to the vertical orientation. This is shown in FIGS. 13A-13C.

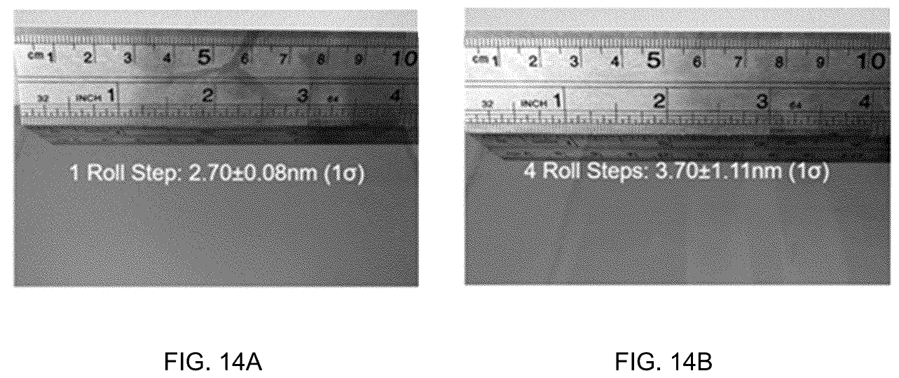

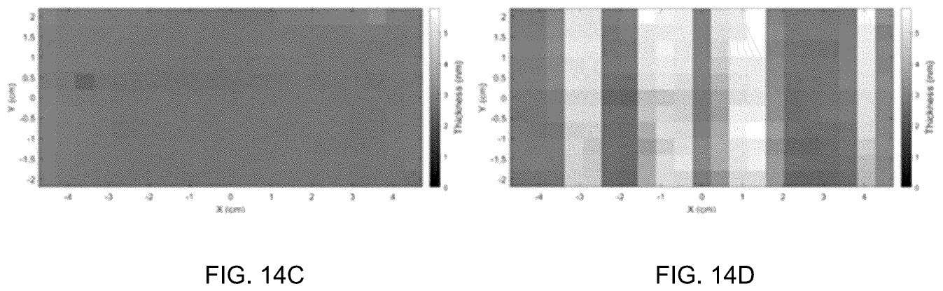

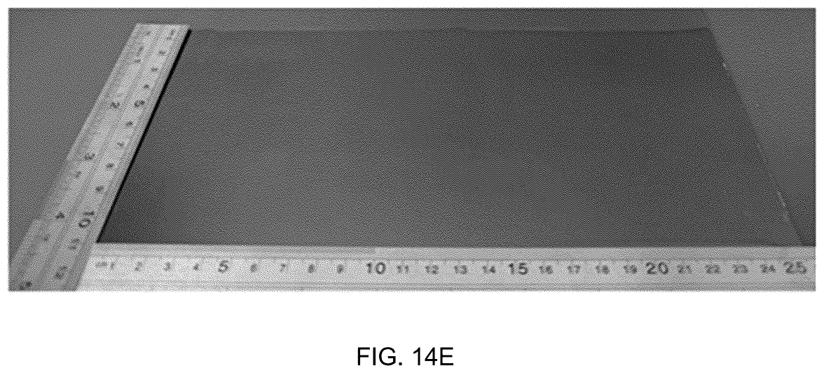

Through confinement of the liquid metal meniscus in front of the roller, we can achieve enhanced deposition areas greater than 15 cm by 30 cm. In principle, the only limitations are the width of the roller and confinement blade along with the quantity of liquid metal and substrate size. FIGS. 14A-14E show a resulting film.

The LMC method is compatible with various metal precursor alloys. Embodiments of this process printed InOₓ as well as ITO at 7 wt %, 10 wt %, and 20 wt % Tin (Sn). Embodiments of this process may be compatible with other substances used in CLMP.

Embodiments of this method were demonstrated from 160 °C up to 250 °C. A wider range of temperatures, such as from room temperature to 500 °C, can be used.

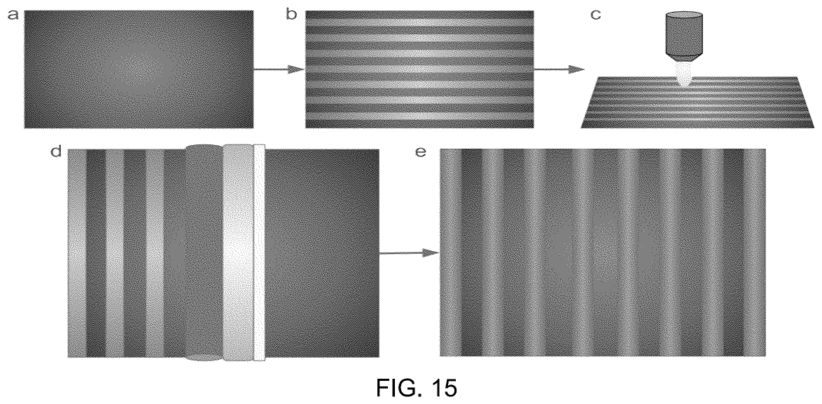

Selective deposition of metal oxide films on dielectric substrates can be achieved via selectively treating the substrates with O₃ plasma in the regions where deposition is desired. The mask (e.g., Kapton) may be used to guide the plasma treatment, after which it is removed before liquid metal printing. The liquid metal printing step can selectively deposit on regions treated by plasma. Embodiments disclosed herein can print features down to the 100 μm length scale. An example of the process is shown in FIG. 15.

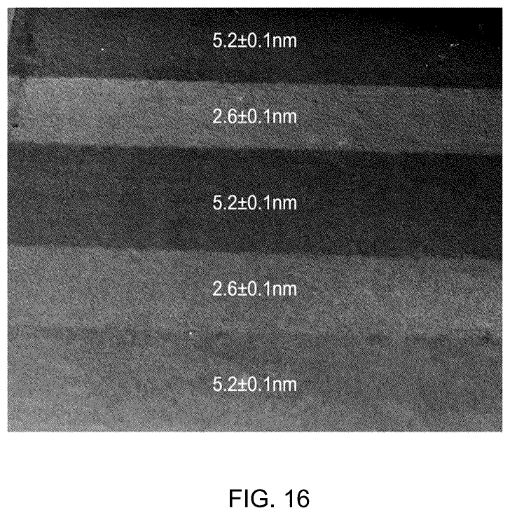

Continuous film layers may be printed over the top of previously patterned layers deposited using embodiments of the method described in this example, which allows creation of films with modulated thickness in different regions. An example is shown in FIG. 16.

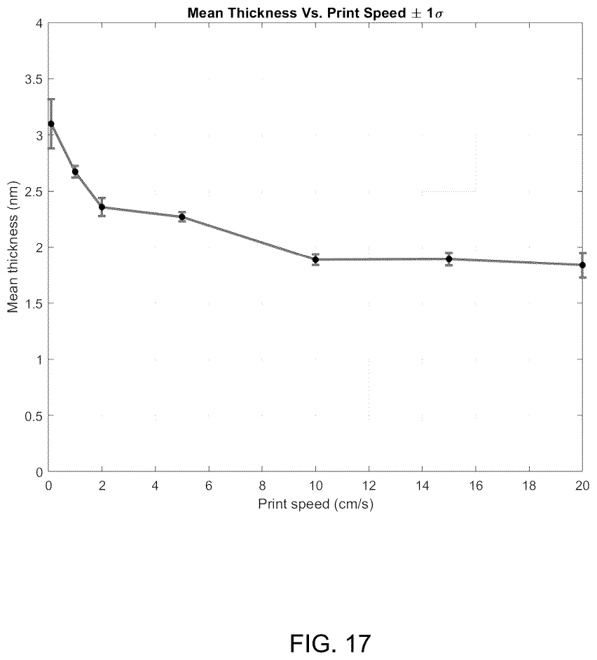

Films can be deposited at speeds from 0.1 cm/s up to 20 cm/s, which is supported by FIG. 17.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A metal oxide film comprising:
a homojunction structure with a metal oxide film, wherein the homojunction structure includes:
at least one layer including a metal, wherein the layer including the metal is crystalline or amorphous; and
at least one less conductive layer that includes the metal.

2. The metal oxide of claim 1, wherein the less conductive layer comprises an amorphous layer or a polycrystalline ternary metal oxide, and wherein the layer including the metal and the less conductive layer form a multilayer channel comprising a front channel and a back channel.

3. The metal oxide film of claim 2, wherein the front channel comprises the layer including the metal and the back channel comprises the at least one less conductive layer.

4. The metal oxide film of claim 2, wherein ternary metal cations of the ternary metal oxide are vertically distributed in the metal oxide film via stacking of the layers.

5. The metal oxide film of claim 1, wherein the metal includes In and the metal oxide film is an InOₓ film or a metal-doped InOₓ film.

6. The metal oxide film of claim 5, wherein the metal-doped InOₓ film is indium tin oxide (ITO).

7. The metal oxide film of claim 1, wherein the metal includes Sn and the metal oxide film is an SnOₓ film or a metal-doped SnOₓ film.

8. The metal oxide film of claim 1, wherein the distribution of the metal in the layer including the metal and the distribution of the metal in the less conductive layer is uniform at the nanoscale.

9. The metal oxide film of claim 1, wherein the layer including the metal and the at least one less conductive layer is from 0.5-12 nm in thickness.

10. The metal oxide film of claim 1, wherein the metal oxide film is from 1-24 nm in thickness.

11. The metal oxide film of claim 1, wherein the metal oxide film has a 0.2-2% tensile strain.

12. The metal oxide film of claim 1, wherein the metal oxide film is a bilayer film.

13. The metal oxide film of claim 1, wherein the metal oxide film is a multilayer film.

14. The metal oxide film of claim 1, wherein the metal oxide film is nanocrystalline.

15. A method of liquid printing comprising:
providing a first workpiece, wherein a surface of the first workpiece includes a dielectric;
providing a second workpiece that includes a metal;
applying the second workpiece onto the first workpiece at a first pressure such that the metal contacts the dielectric; and
forming an alloyed oxide film;
wherein the liquid printing occurs at a temperature of approximately 80 °C to 300 °C, and
wherein the first workpiece and/or the second workpiece is heated to from 100 °C to 300 °C.

16. The method of claim 15, wherein the liquid printing forms a bilayer film.

17. The method of claim 15, wherein the liquid printing forms a multilayer film.

18. The method of claim 15, wherein the alloyed oxide film is nanocrystalline or amorphous.

19. The method of claim 15, wherein the metal includes In and the alloyed oxide film is an InOₓ film or a metal-doped InOₓ film.

20. The method of claim 19, wherein the metal-doped InOₓ film is indium tin oxide (ITO).

21. The method of claim 15, wherein the alloyed oxide film is one of InZnO, InGaZnOₓ, InGaSnOₓ, SnOx, InSnOₓ, GaSnOₓ, SbSnOₓ, InGaOₓ, InSbOₓ, or InZnSnOₓ.

22. The method of claim 15, wherein the dielectric is SiOₓ, AlOₓ, YOₓ, HfOₓ, ZrOₓ, LaOₓ, another rare earth high-k dielectric, or an alloy thereof.

23. The method of claim 15, wherein the dielectric is SiO₂, wherein the metal is In, and wherein the applying includes rolling a roller over the first workpiece.

24. The method of claim 23, wherein the first pressure using the roller is from 0.1 N/cm of roller width to 100 N/cm of roller width.

25. The method of claim 15, wherein the applying forms a homojunction structure.

26. The method of claim 15, wherein the liquid printing occurs at a speed of 0.5 cm/s.
